(19) United States
(12) Patent Application Publication
(10) Pub. No.: US 2025/0221127 A1
(43) Pub. Date: Jul. 3, 2025

(54) DISPLAY DEVICE

(71) Applicant: Samsung Display Co., LTD., Yongin-si (KR)

(72) Inventors: Myunghee HAN, Yongin-si (KR); Junhyeong PARK, Yongin-si (KR); Jiyeon SEO, Yongin-si (KR); Hosik SHIN, Yongin-si (KR); Hyejin JOO, Yongin-si (KR)

(21) Appl. No.: 19/003,022

(22) Filed: Dec. 27, 2024

(30) Foreign Application Priority Data
Dec. 27, 2023 (KR) 10-2023-0193099

(51) Int. Cl. H10H 29/37; H01L 25/075; H10H 29/01; H10H 29/80

(52) U.S. Cl. CPC H10H 29/37; H01L 25/0753; H10H 29/0362; H10H 29/942

(57) ABSTRACT

A display device includes a substrate including a first area and a second area surrounding the first area, a first electrode disposed in the first area, a first bank layer disposed on the first electrode and defining a first opening that overlaps the first electrode and a second opening that overlaps the second area, an intermediate layer disposed on the first electrode, a second electrode disposed on the intermediate layer, and an encapsulation layer disposed on the second electrode and defining a third opening that overlaps the second area, wherein the first bank layer includes a first sub-bank layer and a second sub-bank layer, the second sub-bank layer being disposed on the first-sub bank layer and including a first tip extending toward the first opening and a second tip extending toward the second opening.

This application claims priority to Korean Patent Application No. 10-2023-0193099, filed on Dec. 27, 2023, and all the benefits accruing therefrom, the content of which in its entirety is herein incorporated by reference.

### BACKGROUND

### 1. Field

Embodiments relate to a display device.

### 2. Description of the Related Art

As display devices that visually display electrical signals have been developed, various display devices with excellent characteristics such as thinning, light weight, and low power consumption have been introduced. For example, flexible display devices that may be bent, folded or rolled in the shape of a roll have been introduced. In recent years, research and development of display devices having various structures such as stretchable display devices that may be changed in various forms have been actively conducted.

### SUMMARY

Defects such as cracks, etc., may occur in inorganic layers that constitute a display device due to elongation of the display device. Embodiments include a display device having an enhanced elongation rate. However, this feature is merely illustrative, and the scope of the disclosure is not limited thereto.

Additional features will be set forth in part in the description which follows and, in part, will be apparent from the description, or may be learned by practice of the presented embodiments of the disclosure.

In an embodiment of the disclosure, a display device includes a substrate including a first area and a second area surrounding the first area, a first electrode disposed in the first area, a first bank layer disposed on the first electrode and defining a first opening that overlaps the first electrode and a second opening that overlaps the second area, an intermediate layer disposed on the first electrode, a second electrode disposed on the intermediate layer, and an encapsulation layer disposed on the second electrode and defining a third opening that overlaps the second area. The first bank layer includes a first sub-bank layer and a second sub-bank layer, the second sub-bank layer being disposed on the first-sub bank layer and including a first tip extending toward the first opening and a second tip extending toward the second opening.

In an embodiment, the encapsulation layer may be disposed on the second electrode and may include a first encapsulation layer being in contact with the first sub-bank layer below the first tip and below the second tip and a second encapsulation layer disposed on the first encapsulation layer.

In an embodiment, the first encapsulation layer may define cavities that overlap the second opening, and the second encapsulation layer may extend to cover the cavities.

In an embodiment, the encapsulation layer may further include a third encapsulation layer between the first encapsulation layer and the second encapsulation layer, the third encapsulation layer may overlap the first opening, and the second encapsulation layer may contact the first encapsulation layer outside the third encapsulation layer.

In an embodiment, the display device may further include an inorganic insulating layer between the substrate and the first opening and defining an opening that overlaps the second area, and a filling layer filling in an opening of the inorganic insulating layer.

In an embodiment, each of the first sub-bank layer and the second sub-bank layer may include conductive materials.

In an embodiment, the first sub-bank layer may include a conductive material or an inorganic insulating material, and the second sub-bank layer may include an inorganic insulating material.

In an embodiment, the display device may further include a second bank layer between the first electrode and the first bank layer, and a conductive layer between the second bank layer and the first bank layer and extending into the second area.

In an embodiment, the first area may be provided in plural, and the conductive layer may connect adjacent first areas across the second area.

In an embodiment, the conductive layer may include a first sub-conductive layer and a second sub-conductive layer arranged on the first sub-conductive layer and including a third tip extending toward the first opening.

In an embodiment, the display device may further include dummy stacks arranged on the second sub-bank layer, and the intermediate layer and the second electrode may be separated from and spaced apart from the dummy stacks by the first tip.

In an embodiment of the disclosure, a display device includes a first electrode disposed in a first area, a first bank layer disposed on the first electrode and defining a first opening that overlaps the first electrode, a second opening that overlaps the second area, and a third opening between the first opening and the second opening, an intermediate layer disposed on the first electrode, a second electrode disposed on the intermediate layer, and an encapsulation layer defining a fourth opening that overlaps a second area surrounding the first area, wherein the first bank layer includes a first sub-bank layer and a second sub-bank layer, the second sub-bank layer being disposed on the first-sub bank layer and including a first tip extending toward the first opening, a second tip extending toward the second opening, and a third tip extending toward the third opening.

In an embodiment, the encapsulation layer may be disposed on the second electrode and may include a first encapsulation layer being in contact with the first sub-bank layer below the first tip, below the second tip, and below the third tip, and a second encapsulation layer disposed on the first encapsulation layer.

In an embodiment, the first encapsulation layer may define cavities that overlap the second opening, and the second encapsulation layer may extend to cover the cavities.

In an embodiment, the encapsulation layer may further include a third encapsulation layer between the first encapsulation layer and the second encapsulation layer, the third encapsulation layer may overlap the first opening, and the second encapsulation layer may contact the first encapsulation layer outside the third encapsulation layer.

In an embodiment, the display device may further include an inorganic insulating layer between the substrate and the first electrode and defining an opening that overlaps the second area, and a filling material filling in the opening of the inorganic insulating layer.

In an embodiment, each of the first sub-bank layer and the second sub-bank layer may include conductive materials.

In an embodiment, at least one of the first sub-bank layer and the second sub-bank layer may include an inorganic insulating material.

In an embodiment, the display device may further include a second bank layer between the first electrode and the first bank layer, and a conductive layer between the second bank layer and the first bank layer and extending into the second area.

In an embodiment, the first area may be provided in plural, and the conductive layer may connect adjacent first areas across the second area.

Other features and advantages other than the above description will be clear from the details of the drawings, the claim of claims and the details of the invention.

### BRIEF DESCRIPTION OF THE DRAWINGS

The above and other features and advantages of illustrative embodiments of the disclosure will be more apparent from the following description taken in conjunction with the accompanying drawings, in which:

FIG. 1 is a perspective view schematically illustrating an embodiment of a display device;

FIGS. 2A and 2B are perspective views illustrating a state in which the display device of FIG. 1 is elongated in a first direction;

FIG. 2C is a perspective view illustrating a state in which the display device of FIG. 1 is elongated in a second direction;

FIG. 2D is a perspective view illustrating a state in which the display device of FIG. 1 is elongated in the first direction and the second direction;

FIG. 2E is a perspective view illustrating a state in which the display device of FIG. 1 is elongated in a third direction;

FIG. 3 is a plan view schematically illustrating an embodiment of a display device;

FIGS. 4A through 4C are equivalent circuit diagrams of an embodiment of one pixel of a display device;

FIG. 5 is a cross-sectional view schematically illustrating an embodiment of a display device;

FIG. 6A is a plan view schematically illustrating an embodiment of a display device;

FIG. 6B is a cross-sectional view taken along line A-A′ of FIG. 6A and schematically illustrating the display device;

FIG. 7A is a plan view schematically illustrating an embodiment of a display device;

FIGS. 7B and 7C are cross-sectional views taken along line B-B′ of FIG. 7A and schematically illustrating the display device;

FIG. 8 is a cross-sectional view schematically illustrating an embodiment of a display device;

FIGS. 9A through 9G are cross-sectional views schematically illustrating an embodiment of a method of manufacturing a display device;

FIG. 10 is a cross-sectional view schematically illustrating an embodiment of a display device;

FIGS. 11 and 12 are cross-sectional views schematically illustrating an embodiment of a display device;

FIG. 13 is a cross-sectional view schematically illustrating an embodiment of a display device; and

FIGS. 14A through 14G are perspective views schematically illustrating an embodiment of electronic apparatuses including a display device.

### DETAILED DESCRIPTION

Reference will now be made in detail to embodiments, embodiments of which are illustrated in the accompanying drawings, wherein like reference numerals refer to like elements throughout. In this regard, the illustrated embodiments may have different forms and should not be construed as being limited to the descriptions set forth herein. Accordingly, the embodiments are merely described below, by referring to the drawing figures, to explain features of the description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

Since various modifications and various embodiments are possible, illustrative embodiments are illustrated in the drawings and described in detail in the detailed description. Effects and features of the disclosure, and a method of achieving them will be apparent with reference to embodiments described below in detail in conjunction with the drawings. However, the disclosure is not limited to the embodiments disclosed herein, but may be implemented in a variety of forms.

Hereinafter, embodiments will be described in detail with reference to the accompanying drawings, and the same or corresponding components are denoted by the same reference numerals, and the same reference numerals are assigned and redundant explanations will be omitted.

In the specification, the terms of the first and second, etc., were used for the purpose of distinguishing one element from other elements, not a limited sense.

In the specification, the singular expression includes a plurality of expressions unless the context is clearly different.

In the specification, the terms such as “comprising” or “having” are meant to be the features described in the specification, or the element s are present, and the possibility of one or more other features or elements will be added, is not excluded in advance.

In the specification, when a portion such as a layer, a region, an element or the like is on other portions, this is not only when the portion is on other portions, but also when other portions are interposed therebetween.

In the specification, when a layer, a region, a component, etc., are connected to each other, the layer, the region, and the components are directly connected to each other and/or the layer, the region, and the components may be indirectly connected to each other with other layers, other regions and other components interposed between the layer, the region, and the components. For example, when a layer, a region, a component, etc., are electrically connected to each other in the specification, the layer, the region, the component, etc., are directly electrically connected to each other, and/or the layer, the region, the component, etc., are indirectly electrically connected to each other with other layers, other regions and other components interposed between the layer, the region, and the components.

When it is referred to as “plane” herein, this means when you sees an object part from above (e.g., when looking in a direction perpendicular to an upper surface of a substrate), and when it is referred to as “cross-section”, this means when you see a cross-section in which the object part is cut vertically, from the side.

In the specification, a first component that “overlaps” a second component means that the first component is disposed above or below the second component and at least a part of the first component overlaps the second component on a plane.

In the specification, “A and/or B” is A, B, or A and B. In addition, in the specification, “at least one of A and B” is A, B, or A and B.

In the specification, the x-axis, the y-axis, and the z-axis are not limited to three axes on a Cartesian coordinate system, and may be interpreted in a broad sense including the same. For example, the x-axis, the y-axis, and the z-axis may be perpendicular to each other, but may refer to different directions that are not orthogonal to each other.

In the specification, in the case where some embodiments may be implemented in the present specification, a specific process order may be performed differently from the order described. For example, two processes described in succession may be substantially performed at the same time, or in an opposite order to an order to be described.

In the drawings, for convenience of explanation, the sizes of elements may be exaggerated or reduced. For example, since the size (e.g., thickness) of each component shown in the drawings are arbitrarily indicated for convenience of explanation, the disclosure is not necessarily limited to the illustration.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). The term such as “about” can mean within one or more standard deviations, or within ±30%, 20%, 10%, 5% of the stated value, for example.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

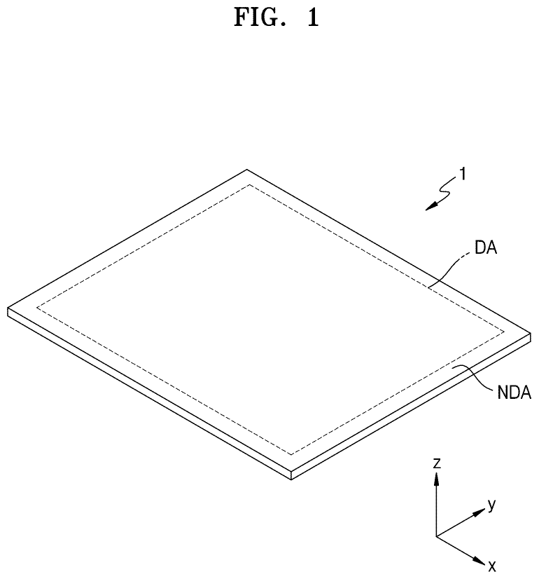

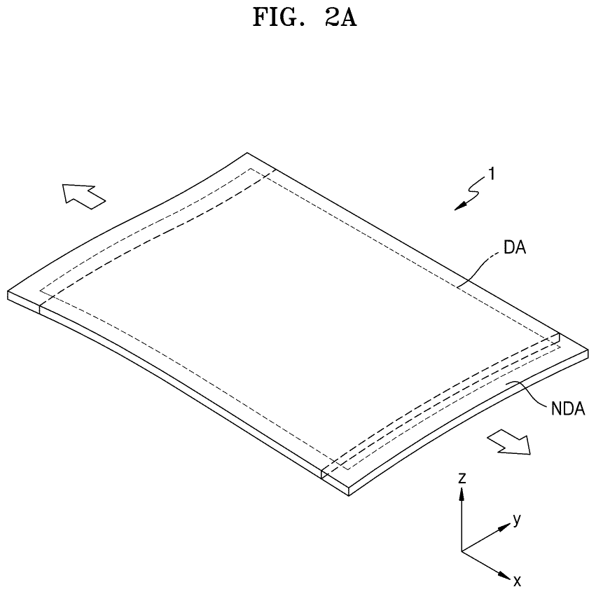

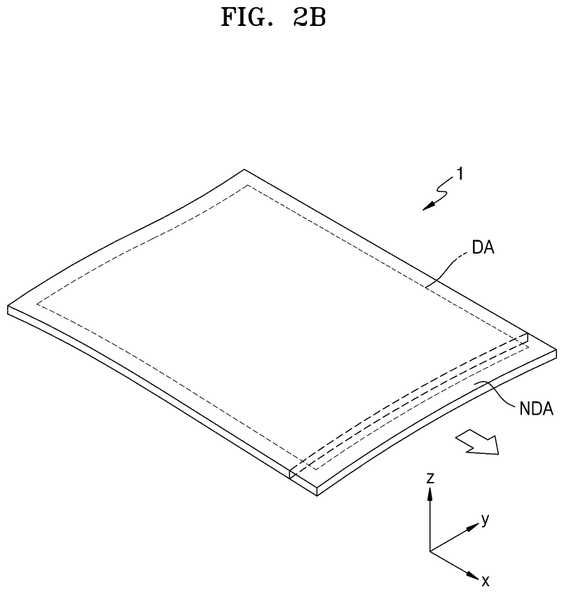

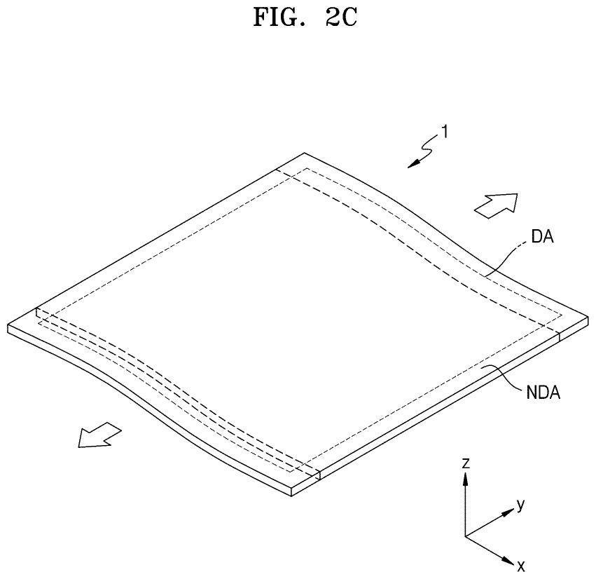

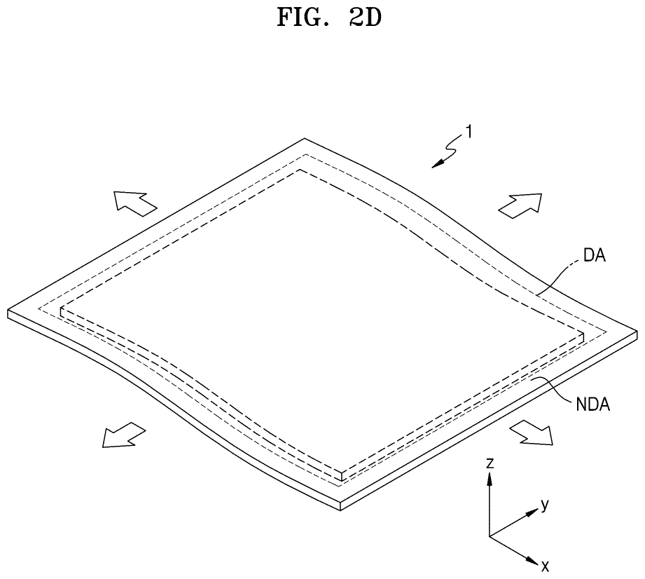

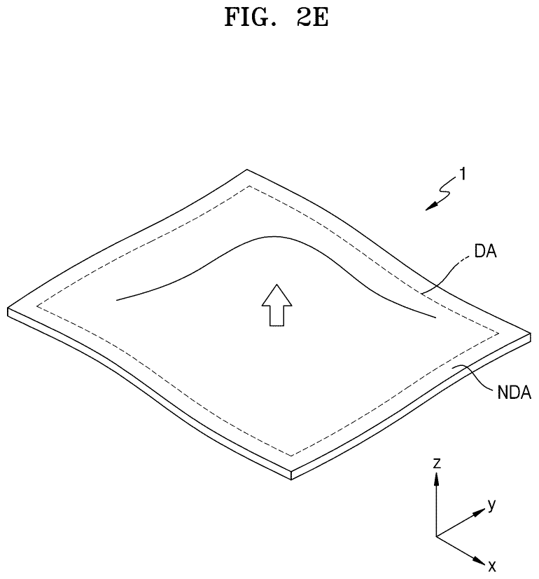

FIG. 1 is a perspective view schematically illustrating an embodiment of a display device, and FIGS. 2A and 2B are perspective views illustrating a state in which the display device of FIG. 1 is elongated in a first direction. FIG. 2C is a perspective view illustrating a state in which the display device of FIG. 1 is elongated in a second direction, FIG. 2D is a perspective view illustrating a state in which the display device of FIG. 1 is elongated in the first direction and the second direction, and FIG. 2E is a perspective view illustrating a state in which the display device of FIG. 1 is elongated in a third direction.

Referring to FIG. 1, the display device 1 may include a display area DA and a non-display area NDA. A plurality of pixels may be included in the display area DA. The display device 1 may provide a predetermined image by light emitted from the plurality of pixels. The non-display area NDA may be outside the display area DA. The non-display area NDA may be an area in which no image is provided, and may surround the display area DA entirely.

The display device 1 may be elongated or shortened in various directions. The display device 1 may be elongated in the first direction (e.g., an x-direction and/or an −x direction) by an external force applied by an external object or a user. In an embodiment, the display area DA and/or the non-display area NDA of the display device 1 may be elongated in the first direction (e.g., the x direction and/or the −x direction), as shown in FIGS. 2A and 2B. In an embodiment, the display area DA and/or the non-display area NDA of the display device 1 may be elongated in the x direction and −x direction, as shown in FIG. 2A, or the display area DA and/or the non-display area NDA of the display device 1 may be elongated in the x direction while one side of the display device 1 is fixed, as shown in FIG. 2B, for example.

The display device 1 may be elongated in the second direction (e.g., a y direction and/or a −y direction) by an external force applied by the external object or the user. In an embodiment, the display area DA and/or the non-display area NDA of the display device 1 may be elongated in the y direction and the −y direction, as shown in FIG. 2C. In another embodiment, the display area DA and/or the non-display area NDA of the display device 1 may be elongated in the y direction or the −y direction while one side of the display device 1 is fixed.

The display device 1 may be elongated in a plurality of directions, e.g., the first direction (e.g., the x direction and/or the −x direction) and the second direction (e.g., the y direction and/or the-y direction) by an external force applied by the external object or a part of the human body. The display area DA and/or the non-display area NDA of the display device 1 may be elongated in an +x direction and a ty direction, as shown in FIG. 2D.

The display device 1 may be elongated in the third direction (e.g., a z direction and/or a −z direction) by an external force applied by the external object or the user. In an embodiment, FIG. 2E illustrates that a part of the display device 1, e.g., a partial region of the display area DA protrudes in the z direction. In another embodiment, a part of the display device 1, e.g., a partial region of the display area DA may protrude in the −z direction (may be recessed in the z direction).

FIGS. 2A through 2E illustrate that the display device 1 is elongated in the first direction, the second direction and/or the third direction, but the disclosure is not limited thereto. In another embodiment, the display device 1 may be variously modified in atypical shapes, such as bending or twisting with two or more axes.

In an embodiment, the display device 1 may be a curved display device in which a part of the display area DA is curved with a preset curvature. In an embodiment, the display device 1 may be a foldable display device that is folded or unfolded based on a folding axis extending in one direction. In another embodiment, the display device 1 may be a rollable display device that may be rolled around a virtual axis.

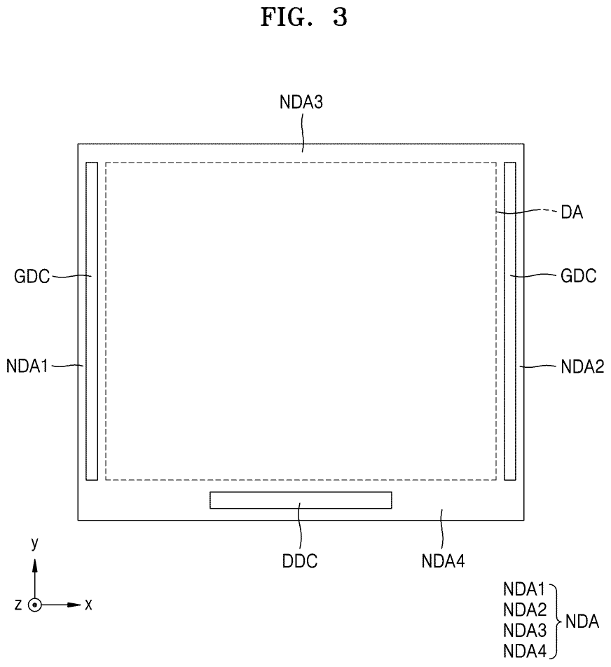

FIG. 3 is a plan view schematically illustrating an embodiment of a display device.

A plurality of pixels may be arranged in the display area DA of the display device 1. Each of the plurality of pixels may include sub-pixels that emit light of different colors. Light-emitting diodes respectively corresponding to the sub-pixels may be arranged in the display area DA. A circuit for providing electrical signals to the light-emitting diodes arranged in the display area DA and transistors electrically connected to the light-emitting diodes may be arranged in the non-display area NDA around the display area DA. A gate driving circuit GDC may be disposed in each of a first non-display area NDA1 and a second non-display area NDA2 at opposite sides of the display area DA therebetween. The gate driving circuit GDC may include drivers for providing electrical signals to a gate electrode of each of the transistors electrically connected to the light-emitting diodes. FIG. 3 illustrates that the gate driving circuit GDC is disposed in each of the first non-display area NDA1 and the second non-display area NDA2, but the disclosure is not limited thereto. In another embodiment, the gate driving circuit GDC may be disposed in only one of the first non-display area NDA1 and the second non-display area NDA2.

The data driving circuit DDC may be disposed in a third non-display area NDA3 and/or a fourth non-display area NDA4, which connect the first non-display area NDA1 and the second non-display area NDA2 to each other. In an embodiment, FIG. 3 illustrates that a data driving circuit DDC is disposed in the fourth non-display area NDA4. In another embodiment, the data driving circuit DDC may be disposed in each of the third non-display area NDA3 and the fourth non-display area NDA4.

FIG. 3 illustrates that the data driving circuit DDC is disposed in the fourth non-display area NDA4 of the display device 1, but the disclosure is not limited thereto. In another embodiment, the display device 1 may further include a flexible circuit board (not shown) electrically connected to the display device 1 through a terminal unit (not shown) disposed in the fourth non-display area NDA4, and the data driving circuit DDC may be disposed on the flexible circuit board as described above.

In some embodiments, an elongation rate of the non-display area NDA may be equal to or less than an elongation rate of the display area DA. In an embodiment, the elongation rate of the non-display area NDA may be different by region. In an embodiment, the first non-display area NDA1, the second non-display area NDA2, and the third non-display area NDA3 may have substantially the same elongation rate, but an elongation rate of the fourth non-display area NDA4 may be less than an elongation rate of each of the first non-display area NDA1, the second non-display area NDA2, and the third non-display area NDA3, for example.

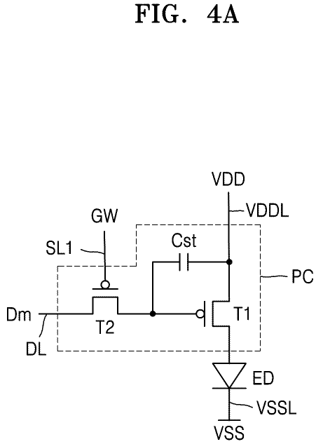

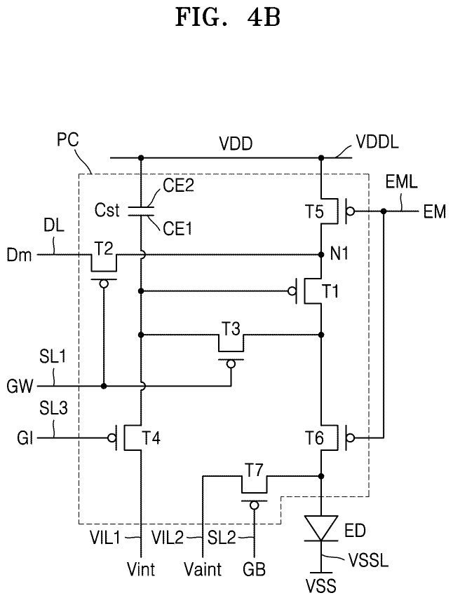

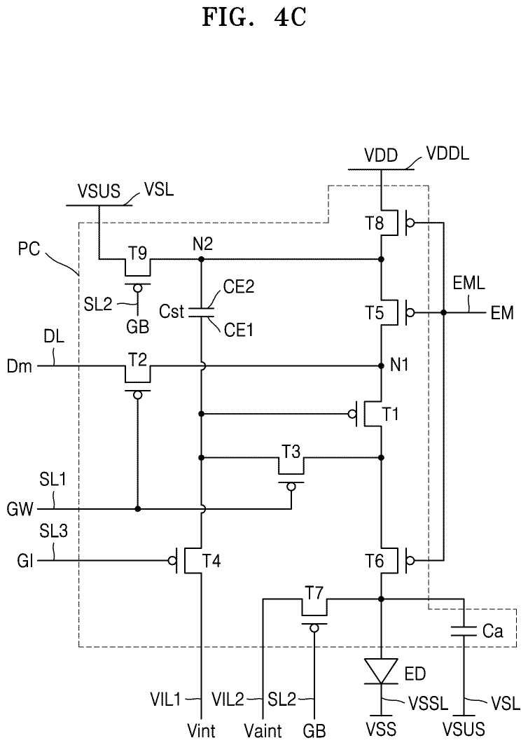

FIGS. 4A through 4C are equivalent circuit diagrams of an embodiment of one pixel of a display device.

Referring to FIG. 4A, a light-emitting diode ED corresponding to a sub-pixel may be electrically connected to a pixel driving circuit portion PC, and the pixel driving circuit portion PC may include a first transistor T1, a second transistor T2, and a storage capacitor Cst. The pixel driving circuit portion PC may be electrically connected to signal lines and a voltage line. The signal lines may include a gate line such as a first scan line SL1, and a data line DL, and the voltage line may include a first voltage line (also referred to as a driving power supply voltage line) VDDL.

The second transistor T2 may be electrically connected to the first scan line SL1 and the data line DL. The first scan line SL1 may provide a first scan signal GW to a gate electrode of the second transistor T2. The second transistor T2 may transmit a data signal Dm input from the data line DL to the first transistor T1 in response to a first scan signal GW input from the first scan line SL1.

The storage capacitor Cst may be connected to the second transistor T2 and the first voltage line VDDL and may store a voltage corresponding to a difference between a voltage transmitted from the second transistor T2 and a first power supply voltage VDD supplied by the first voltage line VDDL.

The first transistor T1 may be a driving transistor and may control a driving current flowing through the light-emitting diode ED. The first transistor T1 may be connected to the first voltage line VDDL and the storage capacitor Cst. The first transistor T1 may control the driving current flowing through the light-emitting diode ED from the first voltage line VDDL in response to a value of the voltage stored in the storage capacitor Cst. The light-emitting diode ED may emit light having predetermined luminance by the driving current. A first electrode (e.g., an anode) of the light-emitting diode ED may be electrically connected to the first transistor T1, and a second electrode (e.g., a cathode) of the light-emitting diode ED may be electrically connected to a second voltage line VSSL for supplying a second power supply voltage (also referred to as a common power supply voltage) VSS.

FIG. 4A illustrates that the pixel driving circuit portion PC includes two transistors and one storage capacitor. However, in another embodiment, the pixel driving circuit portion PC may include three or more transistors with one or more storage capacitor.

Referring to FIG. 4B, the pixel driving circuit portion PC may include a first transistor T1, a second transistor T2, a third transistor T3, a fourth transistor T4, a fifth transistor T5, a sixth transistor T6, a seventh transistor T7, and a storage capacitor Cst.

The pixel driving circuit portion PC may be electrically connected to signal lines and voltage lines. The signal lines may include a gate line such as a first scan line SL1, a second scan line SL2, a third scan line SL3, and an emission control line EML, and a data line DL. The voltage lines may include first and second initialization voltage lines VIL1 and VIL2 and a first voltage line VDDL.

The first voltage line VDDL may transmit the first power supply voltage VDD to the first transistor T1. The first initialization voltage line VIL1 may transmit a first initialization voltage Vint for initializing the first transistor T1 to the pixel driving circuit portion PC. The second initialization voltage line VIL2 may transmit a second initialization voltage Vaint for initializing the first electrode of the light-emitting diode ED to the pixel driving circuit portion PC.

The first transistor T1 may be electrically connected to the first voltage line VDDL via the fifth transistor T5 and may be electrically connected to the light-emitting diode ED via the sixth transistor T6. The first transistor T1 may serve as a driving transistor, may receive the data signal Dm according to a switching operation of the second transistor T2, and may supply a driving current to the light-emitting diode ED.

The second transistor T2 may be a data writing transistor and may be electrically connected to the first scan line SL1 and the data line DL. The second transistor T2 may be electrically connected to the first voltage line VDDL via the fifth transistor T5. The second transistor T2 may be turned on in response to the first scan signal GW transmitted through the first scan line SL1 and may perform a switching operation of transmitting the data signal Dm, which is transmitted to the data line DL, to a first node N1.

The third transistor T3 may be electrically connected to the first scan line SL1 and may be electrically connected to the light-emitting diode ED via the sixth transistor T6. The third transistor T3 may be turned on in response to the first scan signal GW transmitted through the first scan line SL1 and may diode-connect the first transistor T1.

The fourth transistor T4 may be a first initialization transistor and may be electrically connected to the third scan line SL3 and the first initialization voltage line VIL1. The fourth transistor T4 may be turned on in response to a third scan signal GI transmitted through the third scan line SL3, may transmit the first initialization voltage Vint from the first initialization voltage line VIL1 to the gate electrode of the first transistor T1, thereby initializing a voltage of a gate electrode of the first transistor T1. The third scan signal GI may correspond to a first scan signal of another pixel driving circuit portion disposed in the previous row of the pixel driving circuit portion PC.

The fifth transistor T5 may be an operation control transistor, and the sixth transistor T6 may be an emission control transistor. The fifth transistor T5 and the sixth transistor T6 may be electrically connected to the emission control line EML, may be turned on simultaneously in response to an emission control signal EM transmitted through the emission control line EML, and may form a current path through which a driving current may flow in a direction from the first voltage line VDDL to the light-emitting diode ED.

The seventh transistor T7 may be a second initialization transistor and may be electrically connected to the second scan line SL2, the second initialization voltage line VIL2, and the sixth transistor T6. The seventh transistor T7 may be turned on in response to a second scan signal GB transmitted through the second scan line SL2, may transmit the second initialization voltage Vaint from the second initialization voltage line VIL2 to a first electrode of the light-emitting diode ED, thereby initializing the first electrode of the light-emitting diode ED.

The storage capacitor Cst may include a first capacitor electrode CE1 and a second capacitor electrode CE2. The first capacitor electrode CE1 may be electrically connected to the gate electrode of the first transistor T1, and the second capacitor electrode CE2 may be electrically connected to the first voltage line VDDL. The storage capacitor Cst may store and maintain a voltage corresponding to a voltage difference between the first voltage line VDDL and the gate electrode of the first transistor T1, thereby maintaining a voltage applied to the gate electrode of the first transistor T1.

Referring to FIG. 4C, the pixel driving circuit portion PC may include the first transistor T1, the second transistor T2, the third transistor T3, the fourth transistor T4, the fifth transistor T5, the sixth transistor T6, the seventh transistor T7, an eighth transistor T8, a ninth transistor T9, the storage capacitor Cst, and an auxiliary capacitor Ca.

The pixel driving circuit portion PC may be electrically connected to signal lines and voltage lines. The signal lines may include a gate line such as a first scan line SL1, a second scan line SL2, a third scan line SL3, and an emission control line EML, and a data line DL. The voltage lines may include first and second initialization voltage lines VIL1 and VIL2, a maintenance voltage line VSL, and a first voltage line VDDL.

The first voltage line VDDL may transmit the first power supply voltage VDD to the first transistor T1. The first initialization voltage line VIL1 may transmit a first initialization voltage Vint for initializing the first transistor T1 to the pixel driving circuit portion PC. The second initialization voltage line VIL2 may transmit a second initialization voltage Vaint for initializing the first electrode of the light-emitting diode ED to the pixel driving circuit portion PC. The maintenance voltage line VSL may provide a maintenance voltage VSUS to a second node N2, e.g., the second capacitor electrode CE2 of the storage capacitor Cst in an initialization section and a data writing section.

The first transistor T1 may be electrically connected to the first voltage line VDDL via the fifth transistor T5 and the eighth transistor T8 and may be electrically connected to the light-emitting diode ED via the sixth transistor T6. The first transistor T1 may serve as a driving transistor, may receive the data signal Dm according to a switching operation of the second transistor T2, and may supply a driving current to the light-emitting diode ED.

The second transistor T2 may be electrically connected to the first scan line SL1 and the data line DL and may be electrically connected to the first voltage line VDDL via the fifth transistor T5 and the eighth transistor T8. The second transistor T2 may be turned on in response to the first scan signal GW transmitted through the first scan line SL1 and may perform a switching operation of transmitting the data signal Dm, which is transmitted to the data line DL, to the first node N1.

The third transistor T3 may be electrically connected to the first scan line SL1 and may be electrically connected to the light-emitting diode ED via the sixth transistor T6. The third transistor T3 may be turned on in response to the first scan signal GW transmitted through the first scan line SL1 and may diode-connect the first transistor T1, thereby compensating for a threshold voltage of the first transistor T1.

The fourth transistor T4 may be electrically connected to the third scan line SL3 and the first initialization voltage line VIL1, may be turned on in response to the third scan signal GI transmitted through the third scan line SL3, may transmit the first initialization voltage Vint from the first initialization voltage line VIL1 to the gate electrode of the first transistor T1, thereby initializing the voltage of the gate electrode of the first transistor T1. The third scan signal GI may correspond to a first scan signal of another pixel driving circuit portion disposed in the previous row of the pixel driving circuit portion PC.

The fifth transistor T5, the sixth transistor T6, and the eighth transistor T8 may be electrically connected to the emission control line EML, may be turned on simultaneously in response to the emission control signal EM transmitted through the emission control line EML, and may form a current path through which a driving current may flow in a direction from the first voltage line VDDL to the light-emitting diode ED.

The seventh transistor T7 may be a second initialization transistor and may be electrically connected to the second scan line SL2, the second initialization voltage line VIL2, and the sixth transistor T6. The seventh transistor T7 may be turned on in response to a second scan signal GB transmitted through the second scan line SL2, may transmit the second initialization voltage Vaint from the second initialization voltage line VIL2 to a first electrode of the light-emitting diode ED, thereby initializing the first electrode of the light-emitting diode ED.

The ninth transistor T9 may be electrically connected to the second scan line SL2, the second capacitor electrode CE2 of the storage capacitor Cst, and the maintenance voltage line VSL. The ninth transistor T9 may be turned on in response to the second scan signal GB transmitted through the second scan line SL2, and may transmit the maintenance voltage VSUS to the second node N2, e.g., the second capacitor electrode CE2 of the storage capacitor Cst in an initialization section and a data writing section.

Each of the eighth transistor T8 and the ninth transistor T9 may be electrically connected to the second node N2, e.g., the second capacitor electrode CE2 of the storage capacitor Cst. In some embodiments, in the initialization section and the data writing section, the eighth transistor T8 may be turned off, and the ninth transistor T9 may be turned on, and in an emission section, the eighth transistor T8 may be turned on, and the ninth transistor T9 may be turned off. In the initialization section and the data writing section, the second node N2 may enhance uniformity (e.g., long range uniformity (“LRU”)) of brightness of the display device according to voltage drop of the first voltage line VDDL, because the maintenance voltage VSUS is transmitted to the second node N2.

The storage capacitor Cst may include a first capacitor electrode CE1 and a second capacitor electrode CE2. The first capacitor electrode CE1 may be electrically connected to the gate electrode of the first transistor T1, and the second capacitor electrode CE2 may be electrically connected to the eighth transistor T8 and the ninth transistor T9.

An auxiliary capacitor Ca may be electrically connected to the sixth transistor T6, the maintenance voltage line VSL, and the first electrode of the light-emitting diode ED. The auxiliary capacitor Ca may store and maintain a voltage corresponding to a voltage difference between the first electrode of the light-emitting diode ED and the maintenance voltage line VSL while the seventh transistor T7 and the ninth transistor T9 are turned on, thereby preventing black brightness from being increased when the sixth transistor T6 is turned off.

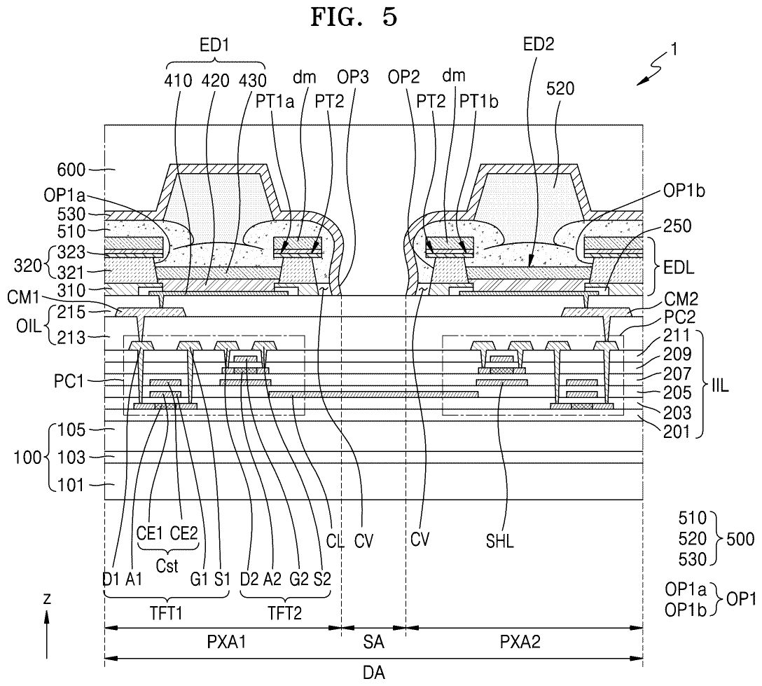

FIG. 5 is a cross-sectional view schematically illustrating an embodiment of a display device 1.

Referring to FIG. 5, the display device 1 in an embodiment may include a substrate 100, and a first sub-pixel and a second sub-pixel, which are arranged on the substrate 100. The first sub-pixel may include a first pixel driving circuit portion PC1, and a first light-emitting diode ED1 electrically connected to the first pixel driving circuit portion PC1. The second sub-pixel may include a second pixel driving circuit portion PC2, and a second light-emitting diode ED2 electrically connected to the second pixel driving circuit portion PC2.

The display device 1 may include a display area DA. The display area DA may include pixel areas (also referred to as first areas) PXA1 and PXA2 in which sub-pixels are arranged, and a segmental area (also referred to as a second area) SA between the pixel areas PXA1 and PXA2. The first pixel area PXA1 and the second pixel area PXA2 may be spaced apart from each other by the segmental area SA, and each of the first pixel area PXA1 and the second pixel area PXA2 may be surrounded by the segmental area SA in a plan view.

The substrate 100 may include regions corresponding to each of the pixel areas PXA1 and PXA2 and the segmental area SA. In the specification, the substrate 100 including the first pixel area PXA1, the second pixel area PXA2 and the segmental area SA may mean that the substrate 100 includes an area corresponding to the first pixel area PXA1, an area corresponding to the second pixel area PXA2 and an area corresponding to the segmental area SA.

The substrate 100 may include an insulating material such as glass, quartz, a polymer resin, or the like. The polymer resin may include polyethersulfone, polyacrylate, polyether imide, polyethylene naphthalate, polyethylene terephthalate, polyphenylene sulfide, polyarylate, polyimide, polycarbonate or cellulose acetate propionate.

The substrate 100 may be provided with a barrier layer as an inorganic material layer and base layers as organic material layers that are alternately arranged. FIG. 5 illustrates that the substrate 100 includes a first base layer 101, a first barrier layer 103 and a second base layer 105, but the disclosure is not limited thereto. In an embodiment, the substrate 100 may further include a second barrier layer as an inorganic material layer between the second base layer 105 and a buffer layer 201.

The first barrier layer 103, etc., may prevent or minimize impurities from penetrating from a lower portion of the substrate 100. In an embodiment, the first barrier layer 103 may include silicon oxide, silicon nitride and/or silicon oxynitride.

The buffer layer 201 may be disposed on the substrate 100. The buffer layer 201 may prevent or reduce impurities from penetrating from the substrate 100 and may provide a base surface that is flat with respect to the first pixel driving circuit portion PC1 and the second pixel driving circuit portion PC2 arranged on the buffer layer 201. The buffer layer 201 may include an inorganic material such as oxide or nitride and may have a single layer or multi-layered structure. In some embodiments, the buffer layer 201 may include silicon oxide, silicon nitride and/or silicon oxynitride.

The first pixel driving circuit portion PC1 and the second pixel driving circuit portion PC2 may be arranged on the buffer layer 201. Each of the first pixel driving circuit portion PC1 and the second pixel driving circuit portion PC2 may include a first thin-film transistor TFT1, a second thin-film transistor TFT2, and a storage capacitor Cst. The first thin-film transistor TFT1 may include a first semiconductor layer A1, a first gate electrode G1, a first source electrode S1, and a first drain electrode D1. The second thin-film transistor TFT2 may include a second semiconductor layer A2, a second gate electrode G2, a second source electrode S2, and a second drain electrode D2. The storage capacitor Cst may include a first capacitor electrode CE1 and a second capacitor electrode CE2. The first pixel driving circuit portion PC1 and the second pixel driving circuit portion PC2 may have similar configurations.

The first semiconductor layer A1 of the first thin-film transistor TFT1 may be disposed on the buffer layer 201. The first semiconductor layer A1 may include a channel region and impurity regions at opposite sides of the channel region. One of the impurity regions at opposite sides of the channel region may correspond to a source region, and a remaining one thereof may correspond to a drain region.

The first semiconductor layer A1 may include a silicon-based semiconductor material, e.g., polysilicon. In some embodiments, the first semiconductor layer A1 may include amorphous silicon.

A first gate insulating layer 203 may be disposed on the first semiconductor layer A1. A first gate electrode G1 may be disposed on the first gate insulating layer 203. The first gate electrode G1 may be disposed to overlap the channel region of the first semiconductor layer A1. The first gate electrode G1 may include a conductive material, e.g., molybdenum (Mo), aluminum (AI), copper (Cu), titanium (Ti), or the like, and may have a single layer or multi-layered structure.

A second gate insulating layer 205 may be disposed on the first gate electrode G1. A second capacitor electrode CE2 may be disposed on the second gate insulating layer 205. The second capacitor electrode CE2 may overlap the first gate electrode G1. The first gate electrode G1 may be unitary as a single body with the first capacitor electrode CE1 of the storage capacitor Cst. The first capacitor electrode CE1 and the second capacitor electrode CE2 may form the storage capacitor Cst. The second capacitor electrode CE2 may include a conductive material, e.g., Mo, Al, Cu, Ti, or the like, and may have a single layer or multi-layered structure.

A first inter-insulating layer 207 may be disposed on the second capacitor electrode CE2. A second semiconductor layer A2 of the second thin-film transistor TFT2 may be disposed on the first inter-insulating layer 207. The second semiconductor layer A2 may include a channel region and impurity regions at opposite sides of the channel region. The second semiconductor layer A2 may include a silicon-based semiconductor material, e.g., a zinc (Zn) oxide-based material. The second semiconductor layer A2 may include a In—Ga—Zn—O (“IGZO”) semiconductor, an In—Sn—Zn—O (“ITZO”) semiconductor, an In—Ga—Sn—Zn—O (“IGTZO”) semiconductor in which metal such as indium (In), gallium (Ga), tin (Sn) is included in ZnO.

A shield layer SHL may be disposed between the first inter-insulating layer 207 and the second gate insulating layer 205 to overlap the second semiconductor layer A2. The shield layer SHL may prevent or reduce degradation of the second thin-film transistor TFT2 by external light.

A third gate insulating layer 209 may be disposed on the second semiconductor layer A2. A second gate electrode G2 may be disposed on the third gate insulating layer 209. The second gate electrode G2 may be disposed to overlap the channel region of the second semiconductor layer A2. The second gate electrode G2 may include a conductive material, e.g., Mo, Al, Cu, Ti, or the like, and may have a single layer or multi-layered structure.

A second inter-insulating layer 211 may be disposed on the second gate electrode G2. A first source electrode S1, a first drain electrode D1, a second source electrode S2, and a second drain electrode D2 may be arranged on the second inter-insulating layer 211. In an embodiment, some of the first source electrode S1, the first drain electrode D1, the second source electrode S2, and the second drain electrode D2 may be omitted. The first source electrode S1, the first drain electrode D1, the second source electrode S2, and the second drain electrode D2 may include Mo, Al, Cu, Ti, or the like and may have a single layer or multi-layered structure.

Components of the first pixel driving circuit portion PC1 and the second pixel driving circuit portion PC2 may be connected to each other through a connection line CL. FIG. 5 illustrates that the connection line CL is disposed between the first gate insulating layer 203 and the second gate insulating layer 205, but the disclosure is not limited thereto. In an embodiment, the connection line CL may be disposed between the buffer layer 201 and the first gate insulating layer 203. In an embodiment, the connection line CL may be disposed between the second inter-insulating layer 211 and a first planarization layer 213.

Each of the first gate insulating layer 203, the second gate insulating layer 205, the first inter-insulating layer 207, the third gate insulating layer 209 and the second inter-insulating layer 211 may include an inorganic insulating material such as silicon oxide, silicon nitride, silicon oxynitride, aluminum oxide, titanium oxide, tantalum oxide, hafnium oxide and/or zinc oxide.

In an embodiment, the first pixel driving circuit portion PC1 may be disposed in the first pixel area PXA1, and the second pixel driving circuit portion PC2 may be disposed in the second pixel area PXA2, but the disclosure is not limited thereto. Only a part of the first pixel driving circuit portion PC1 may overlap the first pixel area PXA1, or the first pixel driving circuit portion PC1 may be offset in the first pixel area PXA1. Similarly, only a part of the second pixel driving circuit portion PC2 may overlap the second pixel area PXA2, or the second pixel driving circuit portion PC2 may be offset in the second pixel area PXA2.

Inorganic material layers between the substrate 100 and a light-emitting diode layer EDL may be indicated as an inorganic insulating layer IIL. In an embodiment, the inorganic insulating layer IIL may include a buffer layer 201, a first gate insulating layer 203, a second gate insulating layer 205, a first inter-insulating layer 207, a third gate insulating layer 209 and a second inter-insulating layer 211, for example.

The first planarization layer 213 may be disposed on the inorganic insulating layer IIL, and a second planarization layer 215 may be disposed on the first planarization layer 213, so as to cover the first source electrode S1, the first drain electrode D1, the second source electrode S2, and the second drain electrode D2. The first planarization layer 213 and the second planarization layer 215 may include a general common use polymer such as benzocyclobutene (“BCB”), polyimide, hexamethyldisiloxane (“HMDSO”), polymethylmethacrylate (“PMMA”) or polystyrene (“PS”), a polymer derivative having a phenol-based group, an acrylic-based polymer, an imide-based polymer, an aryl ether-based polymer, an amide-based polymer, a fluorine-based polymer, a p-xylene-based polymer, or a vinyl alcohol-based polymer, or the like. The first planarization layer 213 and the second planarization layer 215 may provide a base surface that is flat with respect to the light-emitting diode layer EDL disposed above the first planarization layer 213 and the second planarization layer 215.

Organic material layers between the inorganic insulating layer IIL and the light-emitting diode layer EDL may be indicated as an organic insulating layer OIL. In an embodiment, the organic insulating layer OIL may include the first planarization layer 213 and the second planarization layer 215, for example. In an embodiment, each of the first planarization layer 213 and the second planarization layer 215 may have a relatively low modulus of about 3 megapascals (MPa) to about 20 MPa.

A first connection electrode CM1 and a second connection electrode CM2 may be arranged between the first planarization layer 213 and the second planarization layer 215. The first connection electrode CM1 and the second connection electrode CM2 may include Mo, Al, Cu, Ti, or the like, and may have a single layer or multi-layered structure.

The light-emitting diode layer EDL may be disposed on the organic insulating layer OIL. The light-emitting diode layer EDL may include a first light-emitting diode ED1, a second light-emitting diode ED2, a first bank layer 310, and a second bank layer 320.

The first light-emitting diode ED1 may be disposed in the first pixel area PXA1, and the second light-emitting diode ED2 may be disposed in the second pixel area PXA2. Each of the first light-emitting diode ED1 and the second light-emitting diode ED2 may include a first electrode 410, a second electrode 430, and an intermediate layer 420 between the first electrode 410 and the second electrode 430.

First electrodes 410 may be spaced apart from each other on the second planarization layer 215. The first electrode 410 of the first light-emitting diode ED1 may be electrically connected to the first pixel driving circuit portion PC1 through the first connection electrode CM1. The first electrode 410 of the second light-emitting diode ED2 may be electrically connected to the second pixel driving circuit portion PC2 through the second connection electrode CM2.

The first electrode 410 may include a conductive oxide such as indium tin oxide (“ITO”), indium zinc oxide (“IZO”), zinc oxide (ZnO), indium oxide (In₂O₃), indium gallium oxide (“IGO”), or aluminum zinc oxide (“AZO”). In an embodiment, the first electrode 410 may include a reflective layer including silver (Ag), magnesium (Mg), Al, platinum (Pt), palladium (Pd), gold (Au), nickel (Ni), neodymium (Nd), iridium (Ir), chromium (Cr), or any combinations thereof. In an embodiment, the first electrode 410 may further include layers including or consisting of ITO, IZO, ZnO, AZO or In₂O₃ on or under the above-described reflective layer.

The intermediate layer 420 may include a light-emitting layer that emits light of a predetermined color. The light-emitting layer may include polymer or a relatively low molecular weight organic material. In an embodiment, the light-emitting layer may be patterned by a fine metal mask or the like, to correspond to the first electrode 410.

The intermediate layer 420 may include a first functional layer disposed between the first electrode 410 and the light-emitting layer and/or a second functional layer disposed between the light-emitting layer and the second electrode 430. The first functional layer may include a hole transport layer (“HTL”) and/or a hole injection layer (“HIL”), for example. The second functional layer may include an electron transport layer (“ETL”) and/or an electron injection layer (“EIL”).

The second electrode 430 may include a conductive material having a relatively low work function. In an embodiment, the second electrode 430 may include a transparent layer or semi-transparent layer including Ag, Mg, Al, Pt, Pd, Au, Ni, Nd, Ir, Cr, Li, Ca or any alloys thereof. In an alternative embodiment, the second electrode 430 may further include a layer such as ITO, IZO, ZnO, AZO or In₂O₃ on the transparent layer or semi-transparent layer including the above-described materials.

FIG. 5 illustrates that the second electrode 430 as a cathode is disposed on the first electrode 410 as an anode, but the disclosure is not limited thereto. In an embodiment, the first light-emitting diode ED1 and the second light-emitting diode ED2 may have an inverted structure in which the anode is disposed on the cathode.

The first bank layer 310 may be disposed on the second planarization layer 215 to cover an edge of each of the first electrodes 410. The first bank layer 310 may include an inorganic material such as silicon oxide, silicon nitride and/or silicon oxynitride, and may have a single layer or multi-layered structure. The first bank layer 310 may increase a distance between the edge of the first electrode 410 and the second electrode 430, thereby preventing an arc, etc., from occurring.

In an embodiment, a sacrificial layer 250 may be disposed between the first bank layer 310 and the first electrodes 410. The sacrificial layer 250 may be a configuration for preventing or reducing damage of an upper surface of the first electrode 410 in a process of defining first openings OP1 for exposing an upper surface of each of the first electrodes 410. The sacrificial layer 250 may be removed after a process of defining the first openings OP1 is performed, but a part of the sacrificial layer 250 may remain between the first bank layer 310 and the first electrode 410.

The second bank layer 320 may be disposed on the first bank layer 310. In an embodiment, the first bank layer 310 and the second bank layer 320 may have a corresponding shape with each other. In the specification, A and B having a corresponding shape to each other may mean that the shape of A is the same as or similar to the shape of B. In an embodiment, A and B may be formed using the same mask, for example. In an alternative embodiment, A and B may be formed when A is used as a mask of B or B is used as a mask of A. Thus, a boundary between A and B may be substantially matched according to the characteristics of a process and a material, or a shoulder portion, etc., may be formed and spaced apart to a predetermined distance.

The second bank layer 320 may include a first sub-bank layer 321 and a second sub-bank layer 323 disposed on the first sub-bank layer 321. In an embodiment, the first sub-bank layer 321 and the second sub-bank layer 323 may include conductive materials having different etch rates from each other. In an embodiment, the first sub-bank layer 321 may include aluminum or molybdenum, and the second sub-bank layer 323 may include titanium or tantalum, for example.

In another embodiment, the first sub-bank layer 321 may include a conductive material, and the second sub-bank layer 323 may include an inorganic insulating material such as silicon oxide, silicon nitride and/or silicon oxynitride. In another embodiment, each of the first sub-bank layer 321 and the second sub-bank layer 323 may include an inorganic insulating material such as silicon oxide, silicon nitride and/or silicon oxynitride.

The first bank layer 310 and the second bank layer 320 may define a first opening OP1 that overlaps the first electrode 410, and a second opening OP2 that overlaps the segmental area SA. The first opening OP1 may include a 1st-1 opening OP1a that overlaps the first electrode 410 of the first light-emitting diode ED1, and a 1st-2 opening OP1b that overlaps the first electrode 410 of the second light-emitting diode ED2.

The second opening OP2 may be disposed between the first light-emitting diode ED1 and the second light-emitting diode ED2. In an embodiment, a part of the first bank layer 310 and a part of the second bank layer 320 disposed in the first pixel area PXA1, and a part of the first bank layer 310 and a part of the second bank layer 320 located in the second pixel area PXA2 may be separated from each other by the second opening OP2, for example. In an embodiment, a width of the second opening OP2 may be greater than a width of the segmental area SA.

The second bank layer 320 may have an undercut structure in which a part of the first sub-bank layer 321 disposed under the second sub-bank layer 323 is removed. In an embodiment, the second sub-bank layer 323 may include a 1st-1 tip PT1a protruding from a side of the first sub-bank layer 321 toward the 1st-1 opening OP1a, a 1st-2 tip PT1b protruding from the side of the first sub-bank layer 321 toward the 1st-2 opening OP1b, and second tips PT2 protruding from the side of the first sub-bank layer 321 toward the second opening OP2, for example.

Dummy stacks dm may be disposed on an upper surface of the second sub-bank layer 323. The dummy stacks dm may include a first dummy layer including a material for forming the intermediate layer 420 of an adjacent light-emitting diode, and a second dummy layer including a material for forming the second electrode 430. The dummy stacks dm may be spaced apart and separated from the intermediate layer 420 and the second electrode 430 of the adjacent light-emitting diode by each of the 1st-1 tip PT1a and the 1st-2 tip PT1b.

In an embodiment, the second electrode 430 of the light-emitting diode ED1 may be disposed in the 1st-1 opening OP1a and may have an island shape spaced apart and separated from the dummy stacks dm by the 1st-1 tip PT1a, for example. Similarly, the second electrode 430 of the second light-emitting diode ED2 may be disposed in the 1st-2 opening OP1b and may have an island shape spaced apart and separated from the dummy stacks dm by the 1st-2 tip PT1b.

The second electrodes 430 may be in direct contact with the side of the first sub-bank layer 321 toward each of the first openings OP1. In an embodiment, the first sub-bank layer 321 may be electrically connected to a voltage line or a conductive layer for transmitting a power supply voltage (e.g., a second power supply voltage), and the second electrode 430 may receive the power supply voltage through the first sub-bank layer 321. In another embodiment, the second electrodes 430 may be in direct contact with the conductive layer for transmitting a power supply voltage.

An encapsulation layer 500 may be disposed on the light-emitting diode layer EDL to cover the first light-emitting diode ED1 and the second light-emitting diode ED2. The encapsulation layer 500 may include a first inorganic encapsulation layer 510, a second inorganic encapsulation layer 530, and an organic encapsulation layer 520 disposed between the first inorganic encapsulation layer 510 and the second inorganic encapsulation layer 530.

The first inorganic encapsulation layer 510 may be formed by a chemical vapor deposition (“CVD”) method or the like. The first inorganic encapsulation layer 510 may have a relatively excellent step coverage and thus may be in direct contact with a surface of the first sub-bank layer 321 and a surface of the second sub-bank layer 323 that are not covered by the intermediate layer 420 and the second electrode 430. The first inorganic encapsulation layer 510 may form an inorganic contact region in which the second bank layer 320 and each of the first light-emitting diode ED1 and the second light-emitting diode ED2 are sealed. An inorganic contact region in which an inorganic material layer and an inorganic material layer are in direct contact with each other, may space and separate organic material layers from each other, thereby blocking or reducing a penetration path of impurities.

The first inorganic encapsulation layer 510 may define cavities CV that overlap the second opening OP2. In an embodiment, the first inorganic encapsulation layer 510 may extend along the side of the first sub-bank layer 321 toward the second opening OP2, and an end of the first inorganic encapsulation layer 510 may be spaced apart from a bottom surface of the second opening OP2, for example. The cavities CV may be concave portions defined by a lower surface of the first inorganic encapsulation layer 510, a side surface of the second opening OP2, and a bottom surface of the second opening OP2. The cavities CV may be an empty space defined by removing the dummy stacks dm disposed in the second opening OP2.

As a comparative example, in a display device, a second sub-bank layer may not have a second tip, and an end of a first inorganic encapsulation layer may be disposed on an upper surface of the second sub-bank layer. In this structure, dummy stacks on the upper surface of the second sub-bank layer may be removed during a process of defining an opening of the first inorganic encapsulation layer, so that cavities may be defined between the first inorganic encapsulation layer and the second sub-bank layer. The cavities defined in the upper surface of the second sub-bank layer may be extended to the end of the first tip of the second sub-bank layer and may function as a penetration path of impurities. In this case, a width of the cavity may be about 4 micrometers (μm) or more, which is the same as a width of the second sub-bank layer.

By embodiments, the second sub-bank layer 323 includes a second tip PT2 extending toward the second opening OP2, so that the first inorganic encapsulation layer 510 may be in direct contact with a surface of the second sub-bank layer 323 and a surface of the first sub-bank layer 321 at a lower part of the second tip PT2. The cavities CV may be defined outside the second bank layer 320 that surrounds the light-emitting diodes ED1 and ED2. Thus, a distance from the cavities CV to the light-emitting diodes ED1 and ED2 may extend, and the width of the cavity CV may be reduced to about 1.5 μm or less. In an embodiment, the width of the cavity CV may be about 1 μm to about 1.5 μm.

The second inorganic encapsulation layer 530 may cover each of the first pixel area PXA1 and the second pixel area PXA2. The first inorganic encapsulation layer 510 and the second inorganic encapsulation layer 530 may define a third opening OP3 that overlaps the segmental area SA. In an embodiment, the third opening OP3 may be defined by overlapping a first sub-opening defined by the first inorganic encapsulation layer 510 and a second sub-opening defined by the second inorganic encapsulation layer 530, for example. In this case, a width of the first sub-opening may be greater than a width of the second sub-opening.

A part of the first inorganic encapsulation layer 510 and a part of the second inorganic encapsulation layer 530 disposed in the first pixel area PXA1, and a part of the first inorganic encapsulation layer 510 and a part of the second inorganic encapsulation layer 530 disposed in the second pixel area PXA2 may be separated from each other by the third opening OP3. A boundary between the first pixel area PXA1 and the second pixel area PXA2 in a plan view may coincide with a boundary of the second inorganic encapsulation layer 530, and a boundary of the segmental area SA may coincide with a boundary of the third opening OP3.

The first inorganic encapsulation layer 510 and the second inorganic encapsulation layer 530 may include an inorganic material such as silicon oxide, silicon nitride and/or silicon oxynitride, and may have a single layer or multi-layered structure.

An organic encapsulation layer 520 may be disposed between the first inorganic encapsulation layer 510 and the second inorganic encapsulation layer 530. The organic encapsulation layer 520 may bury the first opening OP1, thereby providing a flatter base surface to components arranged above the organic encapsulation layer 520. The organic encapsulation layer 520 may include a polymer resin. In an embodiment, the organic encapsulation layer 520 may include an acrylic-based resin, an epoxy-based resin, polyimide, polyethylene, or the like.

In an embodiment, the organic encapsulation layer 520 may be disposed to correspond to each of the light-emitting diodes ED1 and ED2 through an inkjet process or a photo-patterning process. In an embodiment, the organic encapsulation layer 520 may be disposed to overlap each of the 1st-1 opening OP1a and the 1st-2 opening OP1b, for example. The first inorganic encapsulation layer 510 and the second inorganic encapsulation layer 530 may be in direct contact with each other outside the organic encapsulation layer 520, thereby forming an inorganic contact region.

The first bank layer 310, the second bank layer 320, the first inorganic encapsulation layer 510, and the second inorganic encapsulation layer 530, which are inorganic material layers, may not be arranged in the segmental area SA. In other words, the segmental area SA may be an area in which the first bank layer 310, the second bank layer 320 and the encapsulation layer 500 do not overlap each other. When the display device 1 is elongated or is bent, stress concentrated on the inorganic material layers may be dispersed by the segmental area SA. Thus, defects such as cracks of the inorganic material layers may be reduced or prevented, and the elongation rate of the display device 1 may be enhanced.

A third planarization layer 600 may be disposed on the encapsulation layer 500. The third planarization layer 600 may provide a flat base surface to components arranged above the third planarization layer 600, e.g., a touch input layer or the like. The third planarization layer 600 may include a polymer resin. In an embodiment, the third planarization layer 600 may include an acrylic-based resin, an epoxy-based resin, polyimide, polyethylene, or the like. In some embodiments, the third planarization layer 600 may have a relatively low modulus of about 3 MPa to about 20 MPa, for example.

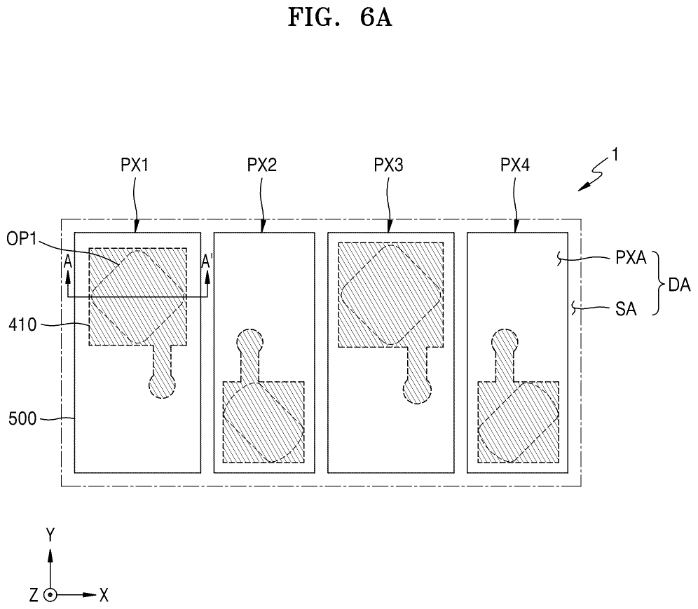

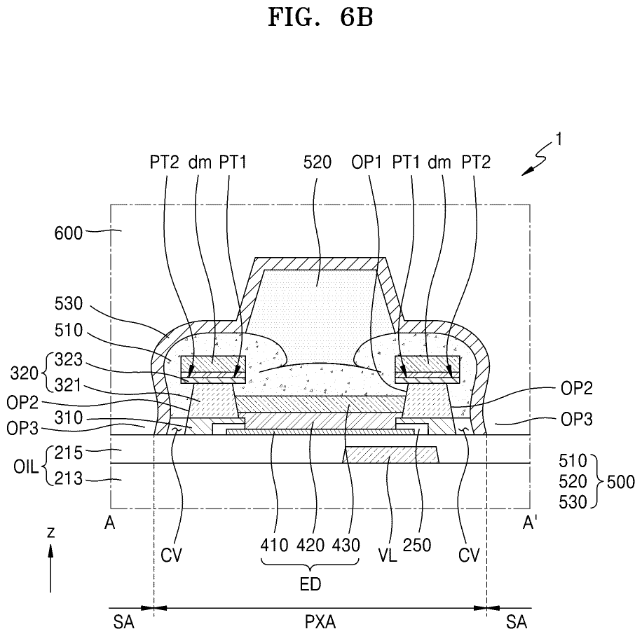

FIG. 6A is a plan view schematically illustrating an embodiment of the display device 1, and FIG. 6B is a cross-sectional view taken along line A-A′ of FIG. 6A and schematically illustrating the display device 1. In FIG. 6B, the configuration of the substrate 100 to the second inter-insulating layer 211 of the display device 1 shown in FIG. 5 is omitted, and the organic insulating layer OIL, the light-emitting diode EDL and the encapsulation layer 500 are mainly shown.

Referring to FIG. 6A, the display device 1 may include a display area DA, and the display area DA may include pixel areas PXA, and a segmental area SA between the pixel areas PXA. The pixel areas PXA may be spaced apart from each other by the segmental area SA, and each of the pixel areas PXA may be surrounded by the segmental area SA in a plan view.

A plurality of sub-pixels PX1, PX2, PX3, and PX4 may be arranged in the display area DA. The plurality of sub-pixels PX1, PX2, PX3, and PX4 may be arranged in various shapes. Here, the arrangement shape of the sub-pixels PX1, PX2, PX3, and PX4 may correspond to a position of the first opening OP1 for defining a light-emitting region. The sub-pixels PX1, PX2, PX3, and PX4 may be arranged in various forms such as a stripe arrangement, a pentile® arrangement (e.g., a diamond arrangement), a mosaic arrangement, or the like, and may realize images. In this regard, FIG. 6A illustrates the sub-pixels PX1, PX2, PX3, and PX4 arranged in the pentile® arrangement.

Each of the sub-pixels PX1, PX2, PX3, and PX4 may include a light-emitting diode that emits red light, green light, blue light or white light, and the light-emitting diode may be electrically connected to a pixel driving circuit portion. In an embodiment, the first sub-pixel PX1 may include a first light-emitting diode that emits red light, and a first pixel driving circuit portion, and the second sub-pixel PX2 may include a second light-emitting diode that emits green light, and a second pixel driving circuit portion, and the third sub-pixel PX3 may include a third light-emitting diode that emits blue light, and a third pixel driving circuit portion, for example. Each of the light-emitting diodes may include a first electrode 410.

In an embodiment, one first electrode 410 may be disposed in one pixel area PXA, and the encapsulation layer 500 may be disposed to cover the pixel area PXA. The encapsulation layer 500 may define the third opening OP3 that overlaps the segmental area SA.

In an embodiment, sizes and/or shapes of the first electrode 410 of the first sub-pixel PX1, the first electrode 410 of the second sub-pixel PX2, and the first electrode 410 of the third sub-pixel PX3 may be different from each other. In this case, sizes and/or shapes of the pixel areas PXA may be different from each other according to sizes and/or shapes of the first electrodes 410. In an embodiment, a fourth sub-pixel PX4 may have a structure which is substantially identical to that of the second sub-pixel PX2. FIG. 6A illustrates that one pixel area PXA defines an approximately quadrangular shape, e.g., rectangular shape, but the disclosure is not limited thereto. The pixel area PXA may have other polygonal shapes, an elliptical shape, or an atypical shape.

Referring to FIG. 6B, one light-emitting diode ED may be disposed in one pixel area PXA. The segmental area SA may be disposed outside the pixel area PXA to surround the pixel area PXA.

A power supply voltage line VL may be disposed on the first planarization layer 213. In an embodiment, the power supply voltage line VL may be a second voltage line (refer to VSSL of FIG. 4A) for supplying a second power supply voltage (refer to VSS of FIG. 4A). In an embodiment, the first sub-bank layer 321 may be electrically connected to the power supply voltage line VL through a contact hole that penetrates the first bank layer 310 and the second planarization layer 215. In another embodiment, a conductive layer for transmitting the second power supply voltage may be disposed between the first bank layer 310 and the second bank layer 320, and the first sub-bank layer 321 may receive the second power supply voltage through the conductive layer.

The second planarization layer 215 may be disposed on the first planarization layer 213 to cover the power supply voltage line VL. The light-emitting diode ED may be disposed on the second planarization layer 215. The light-emitting diode ED may include a first electrode 410, a second electrode 430 on the first electrode 410, and an intermediate layer 420 between the first electrode 410 and the second electrode 430.

The first bank layer 310 may be disposed on the second planarization layer 215 to cover an edge of the first electrode 410. The second bank layer 320 may be disposed on the first bank layer 310. The second bank layer 320 may have a shape corresponding to the shape of the first bank layer 310. The second bank layer 320 may include a first sub-bank layer 321 and a second sub-bank layer 323 disposed on the first sub-bank layer 321. The first bank layer 310 and the second bank layer 320 may define a first opening OP1 that overlaps the first electrode 410, and a second opening OP2 that overlaps the segmental area SA. The second opening OP2 may surround the first electrode 410. The second electrode 430 may be in direct contact with the side of the first sub-bank layer 321 inside the first opening OP1.

The second sub-bank layer 323 may include a first tip PT1 extending toward the first opening OP1 and a second tip PT2 extending toward the second opening OP2. The first tip PT1 may have a closed-loop shape extending along the edge of the first opening OP1. The second tip PT2 may have a closed-loop shape extending along the edge of the second opening OP2.

Dummy stacks dm may be disposed on an upper surface of the second sub-bank layer 323. The dummy stacks dm may be spaced apart and separated from the intermediate layer 420 and the second electrode 430 of the adjacent light-emitting diode by the first tip PT1.

The encapsulation layer 500 may be disposed on the second electrode 430 and the dummy stacks dm to cover the light-emitting diode ED. The encapsulation layer 500 may include a first inorganic encapsulation layer 510, a second inorganic encapsulation layer 530, and an organic encapsulation layer 520 disposed between the first inorganic encapsulation layer 510 and the second inorganic encapsulation layer 530.

The encapsulation layer 500 may be disposed to seal one light-emitting diode ED. The first inorganic encapsulation layer 510 may cover an entirety of an upper surface of the second electrode 430, and upper surfaces and side surfaces of the dummy stacks dm. The first inorganic encapsulation layer 510 may be in direct contact with the surface of the first sub-bank layer 321 and the surface of the second sub-bank layer 323 below the first tip PT1 and the second tip PT2, thereby forming an inorganic contact region.

The first inorganic encapsulation layer 510 may extend along the side of the first sub-bank layer 321 toward the second opening OP2 and may be spaced apart from the bottom surface of the second opening OP2 by the cavities CV. In other words, the first inorganic encapsulation layer 510 may be spaced apart from the upper surface of the second planarization layer 215. The cavities CV may overlap the second opening OP2 and may be disposed outside the second bank layer 320 based on the light-emitting diode ED.

The organic encapsulation layer 520 may be disposed to correspond to the first electrode 410 so as to bury the first opening OP1. An end of the organic encapsulation layer 520 may overlap an upper surface of the second sub-bank layer 323 and may be inside an end of the second tip PT2 in a plan view.

The second inorganic encapsulation layer 530 may be disposed on the first inorganic encapsulation layer 510 and the organic encapsulation layer 520 and may cover the cavities CV. The first inorganic encapsulation layer 510 and the second inorganic encapsulation layer 530 may cover the entirety of the surface of the pixel area PXA and may define a third opening OP3 that overlaps the segmental area SA. A width of the third opening OP3 may be the same as a width of the segmental area SA and less than a width of the second opening OP2. The third opening OP3 may surround the light-emitting diode ED.

The first bank layer 310, the second bank layer 320 and the encapsulation layer 500 may not be arranged in the segmental area SA. A part of the first bank layer 310, a part of the second bank layer 320, and a part of the encapsulation layer 500 may have an island shape separated from a peripheral area with the segmental area SA therebetween. A third planarization layer 600 may be disposed on the second inorganic encapsulation layer 530.

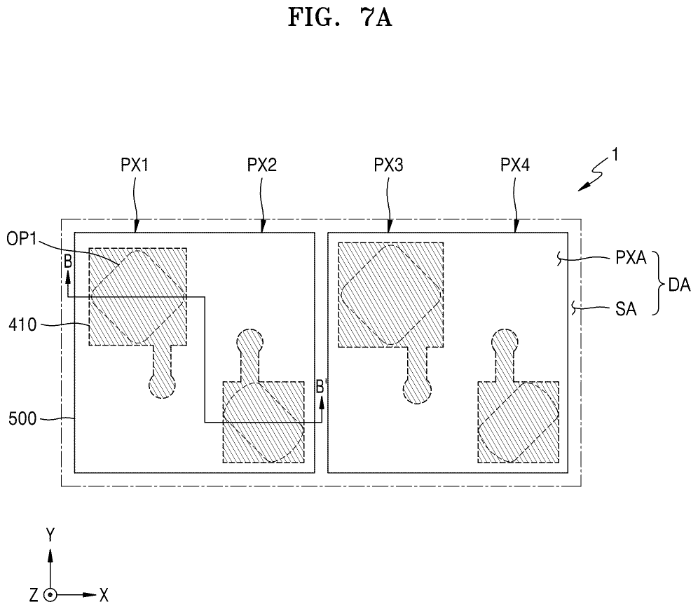

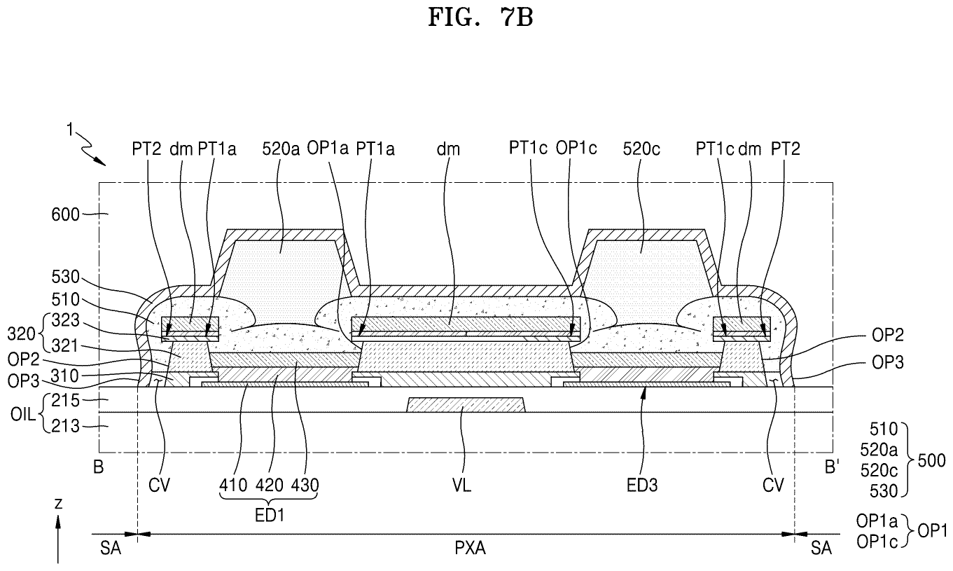

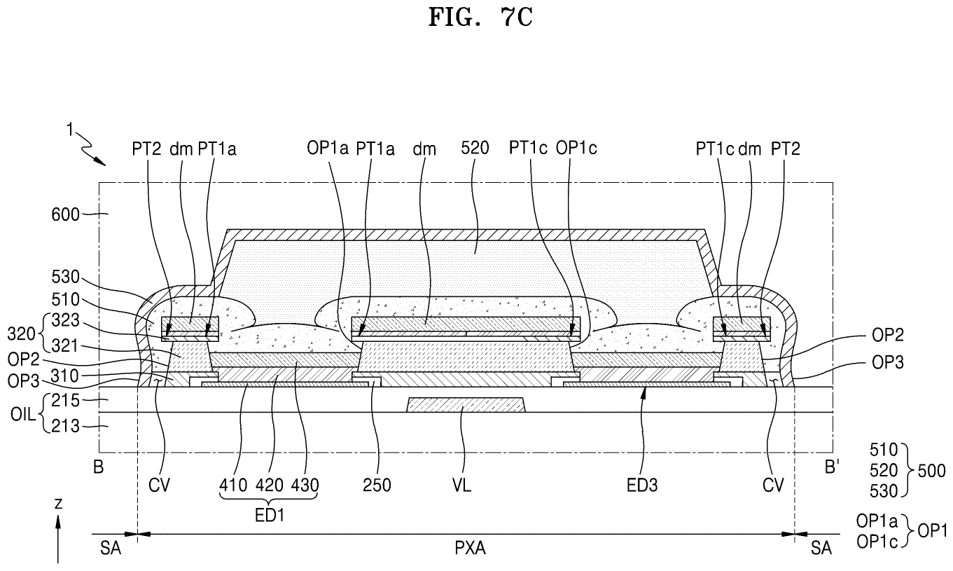

FIG. 7A is a plan view schematically illustrating an embodiment of a display device, and FIG. 7B is a cross-sectional view taken along line B-B′ of FIG. 7A and schematically illustrating the display device.

Referring to FIG. 7A, a display area DA may include pixel areas PXA and a segmental area SA between the pixel areas PXA. The pixel areas PXA may be spaced apart from each other by the segmental area SA, and each of the pixel areas PXA may be surrounded by the segmental area SA in a plan view.

Two or more sub-pixels PX1, PX2, PX3, and PX4 may be arranged in one pixel area PXA. In an embodiment, two first electrodes 410 may be arranged in the pixel area PXA. In an embodiment, a first electrode 410 of the first sub-pixel PX1 and a first electrode 410 of the second sub-pixel PX2 may be arranged in one pixel area PXA, and a first electrode 410 of the third sub-pixel PX3 and a first electrode 410 of the fourth sub-pixel PX2 may be arranged in another pixel area PXA, for example. In another embodiment, a plurality of sub-pixels PX1, PX2, PX3, and PX4 that constitute one pixel unit may be arranged in one pixel area PXA.

An encapsulation layer 500 may be disposed to cover the pixel area PXA. The encapsulation layer 500 may define the third opening OP3 that overlaps the segmental area SA. FIG. 7A illustrates that one pixel area PXA defines an approximately quadrangular shape, e.g., rectangular shape, but the disclosure is not limited thereto. The pixel area PXA may have other polygonal shapes, an elliptical shape, or an atypical shape.

Referring to FIGS. 7B and 7C, a first light-emitting diode ED1 and a third light-emitting diode ED3 may be arranged in one pixel area PXA. The segmental area SA may be disposed outside the pixel area PXA to surround the pixel area PXA.

A power supply voltage line VL may be disposed on the first planarization layer 213. In an embodiment, the power supply voltage line VL may be a second voltage line (refer to VSSL of FIG. 4A) for supplying a second power supply voltage (refer to VSS of FIG. 4A). In an embodiment, the first sub-bank layer 321 may be electrically connected to the power supply voltage line VL through a contact hole that penetrates the first bank layer 310 and the second planarization layer 215. In another embodiment, the power supply voltage line VL may be omitted, and a conductive layer configured to transmit a second power supply voltage may be disposed between the first bank layer 310 and the second bank layer 320.

The second planarization layer 215 may be disposed on the first planarization layer 213 to cover the power supply voltage line VL. A first light-emitting diode ED1 and a third light-emitting diode ED3 may be arranged on the second planarization layer 215. Each of the first light-emitting diode ED1 and the third light-emitting diode ED3 may include a first electrode 410, a second electrode 430 on the first electrode 410, and an intermediate layer 420 between the first electrode 410 and the second electrode 430.

The first bank layer 310 may be disposed on the second planarization layer 215 to cover an edge of the first electrode 410. The second bank layer 320 may be disposed on the first bank layer 310. The second bank layer 320 may correspond to the shape of the first bank layer 310.

The second bank layer 320 may include a first sub-bank layer 321 and a second sub-bank layer 323 disposed on the first sub-bank layer 321. The first bank layer 310 and the second bank layer 320 may define a first opening OP1 that overlaps the first electrodes 410, and a second opening OP2 that overlaps the segmental area SA. The first opening OP1 may include a 1st-1 opening OP1a that overlaps the first electrode 410 of the first light-emitting diode ED1, and a 1st-3 opening OP1c that overlaps the first electrode 410 of the third light-emitting diode ED3. The second opening OP2 may surround the first electrode 410 of the first light-emitting diode ED1 and the first electrode 410 of the third light-emitting diode ED3.

The second electrode 430 of the first light-emitting diode ED1 may be in direct contact with a side surface of the first sub-bank layer 321 inside the 1st-1 opening OP1a. The second electrode 430 of the third light-emitting diode ED3 may be in direct contact with a side surface of the first sub-bank layer 321 inside the 1st-3 opening OP1c.

The second sub-bank layer 323 may include a first tip PT1 extending toward the first openings OP1 and a second tip PT2 extending toward the second opening OP2. The first tip PT1 may include a 1st-1 tip PT1a extending toward the 1st-1 opening OP1a, and a 1st-3 tip PT1c extending toward the 1st-3 opening OP1c. The 1st-1 tip PT1a may have a shape of a closed loop that extends along an edge of the 1st-1 opening OP1a. The 1st-3 tip PT1c may have a shape of a closed loop that extends along an edge of the 1st-3 opening OP1c. The second tip PT2 may have a closed-loop shape extending along the edge of the second opening OP2.

Dummy stacks dm may be disposed on an upper surface of the second sub-bank layer 323. The dummy stacks dm may be spaced apart from and separated from the intermediate layer 420 and the second electrode 430 of the first light-emitting diode ED1 by the 1st-1 tip PT1a and may be spaced apart from and separated from the intermediate layer 420 and the second electrode 430 of the third light-emitting diode ED3 by the 1st-3 tip PT1c.

An encapsulation layer 500 may be disposed to cover the first light-emitting diode ED1 and the third light-emitting diode ED3. The encapsulation layer 500 may include a first inorganic encapsulation layer 510, a second inorganic encapsulation layer 530, and an organic encapsulation layer 520 disposed between the first inorganic encapsulation layer 510 and the second inorganic encapsulation layer 530.

The encapsulation layer 500 may be commonly disposed to seal the first light-emitting diode ED1 and the third light-emitting diode ED3. In an embodiment, the first inorganic encapsulation layer 510 may cover an entirety of an upper surface of the second electrode 430 of the first light-emitting diode ED1, an upper surface of the second electrode 430 of the third light-emitting diode ED3, and upper surfaces and side surfaces of the dummy stacks dm. The first inorganic encapsulation layer 510 may be in direct contact with the surface of the first sub-bank layer 321 and the surface of the second sub-bank layer 323 below the first tip PT1 and the second tip PT2, thereby forming an inorganic contact region.

The first inorganic encapsulation layer 510 may extend along the side of the first sub-bank layer 321 toward the second opening OP2 and may be spaced apart from the bottom surface of the second opening OP2 by the cavities CV. The cavities CV may overlap the second opening OP2 and may be disposed outside the second bank layer 320 that surrounds the light-emitting diode ED.

The organic encapsulation layer 520 may be disposed on the first inorganic encapsulation layer 510 so as to bury the first opening OP1. In an embodiment, as shown in FIG. 7B, the organic encapsulation layer 520 may be disposed to correspond to each of the 1st-1 opening OP1a and the 1st-3 opening OP1c. In an embodiment, the organic encapsulation layer 520 may include a first organic encapsulation layer 520a that overlaps the 1st-1 opening OP1a, and a second organic encapsulation layer 520c that overlaps the 1st-3 opening OP1c, for example. The first organic encapsulation layer 520a and the second organic encapsulation layer 520c may be spaced apart from each other. In another embodiment, as shown in FIG. 7C, the organic encapsulation layer 520 may be unitary as a single body within one pixel area PXA, so as to bury the 1st-1 opening OP1a and the 1st-3 opening OP1c.

The second inorganic encapsulation layer 530 may be disposed on the first inorganic encapsulation layer 510 and the organic encapsulation layer 520 and may cover the cavities CV. The first inorganic encapsulation layer 510 and the second inorganic encapsulation layer 530 may cover the entirety of the surface of the pixel area PXA and may define a third opening OP3 that overlaps the segmental area SA. A width of the third opening OP3 may be the same as a width of the segmental area SA and less than a width of the second opening OP2. The third opening OP3 may surround the first light-emitting diode ED1 and the third light-emitting diode ED3. A third planarization layer 600 may be disposed on the second inorganic encapsulation layer 530.

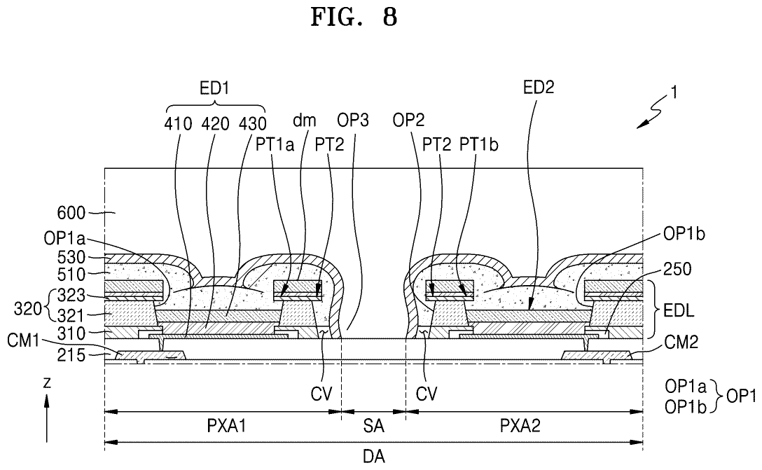

FIG. 8 is a cross-sectional view schematically illustrating an embodiment of a display device.

Referring to FIG. 8, a display device 1 may include a first pixel area PXA1, a second pixel area PXA2, and a segmental area SA between the first pixel area PXA1 and the second pixel area PXA2.

The first light-emitting diode ED1 may be disposed in the first pixel area PXA1, and the second light-emitting diode ED2 may be disposed in the second pixel area PXA2. Each of the first light-emitting diode ED1 and the second light-emitting diode ED2 may include a first electrode 410, a second electrode 430 on the first electrode 410, and an intermediate layer 420 between the first electrode 410 and the second electrode 430.

A first electrode 410 of the first light-emitting diode ED1 and a first electrode 410 of the second light-emitting diode ED2 may be spaced apart from each other and disposed on the second planarization layer 215. The first electrode 410 of the first light-emitting diode ED1 may be electrically connected to a first pixel driving circuit portion through the first connection electrode CM1. The first electrode 410 of the second light-emitting diode ED2 may be electrically connected to a second pixel driving circuit portion through the second connection electrode CM2.

The first bank layer 310 may be disposed on the second planarization layer 215 to cover an edge of each of the first electrodes 410. The second bank layer 320 may be disposed on the first bank layer 310. The second bank layer 320 may include a first sub-bank layer 321 and a second sub-bank layer 323 disposed on the first sub-bank layer 321.

The first bank layer 310 and the second bank layer 320 may define a first opening OP1 that overlaps the first electrode 410, and a second opening OP2 that overlaps the segmental area SA. The first opening OP1 may include a 1st-1 opening OP1a that overlaps the first electrode 410 of the first light-emitting diode ED1, and a 1st-2 opening OP1b that overlaps the first electrode 410 of the second light-emitting diode ED2. A part of the first bank layer 310 and a part of the second bank layer 320 disposed in the first pixel area PXA1 may be separated from a part of the first bank layer 310 and a part of the second bank layer 320 disposed in the second pixel area PXA2 by the second opening OP2.

The second bank layer 320 may have an undercut structure in which a part of the first sub-bank layer 321 disposed under the second sub-bank layer 323 is removed. In an embodiment, the second sub-bank layer 323 may include a 1st-1 tip PT1a extending toward the 1st-1 opening OP1a, and a 1st-2 tip PT1b extending toward the 1st-2 opening OP1b, and a second tip PT2 extending toward the second opening OP2, for example. Dummy stacks dm may be disposed on an upper surface of the second sub-bank layer 323.

An encapsulation layer 500 may be disposed on the light-emitting diode layer EDL to cover the first light-emitting diode ED1 and the second light-emitting diode ED2. The encapsulation layer 500 may include a first inorganic encapsulation layer 510 and a second inorganic encapsulation layer 530.

The first inorganic encapsulation layer 510 may be in direct contact with the surface of the first sub-bank layer 321 and the surface of the second sub-bank layer 323 that are not covered by the intermediate layer 420 and the second electrode 430, thereby forming an inorganic contact region. The first inorganic encapsulation layer 510 may define cavities CV that overlap the second opening OP2.

The first inorganic encapsulation layer 510 and the second inorganic encapsulation layer 530 may define a third opening OP3 that overlaps the segmental area SA. A part of the first inorganic encapsulation layer 510 and a part of the second inorganic encapsulation layer 530 disposed in the first pixel area PXA1, and a part of the first inorganic encapsulation layer 510 and a part of the second inorganic encapsulation layer 530 disposed in the second pixel area PXA2 may be separated from each other by the third opening OP3.

In an embodiment, the organic encapsulation layer 520 may be omitted, and an upper surface of the first inorganic encapsulation layer 510 may be in direct contact with the second inorganic encapsulation layer 530. A third planarization layer 600 may be disposed on the second inorganic encapsulation layer 530. Bending by the first opening OP1 and the second opening OP2 may be buried and planarized by the third planarization layer 600.

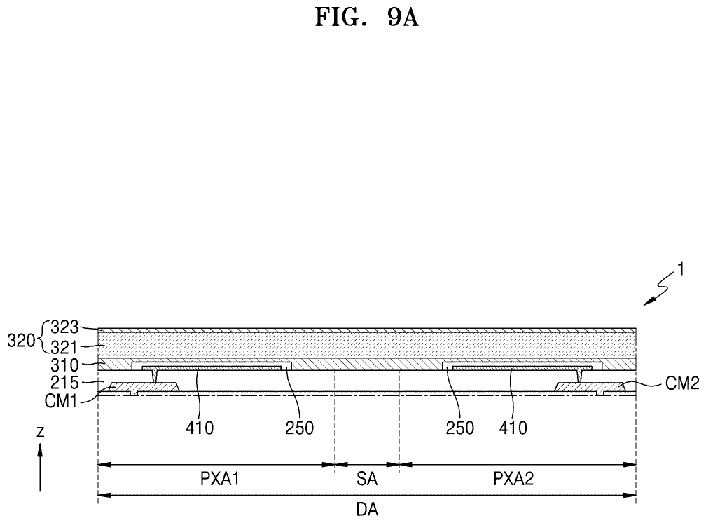

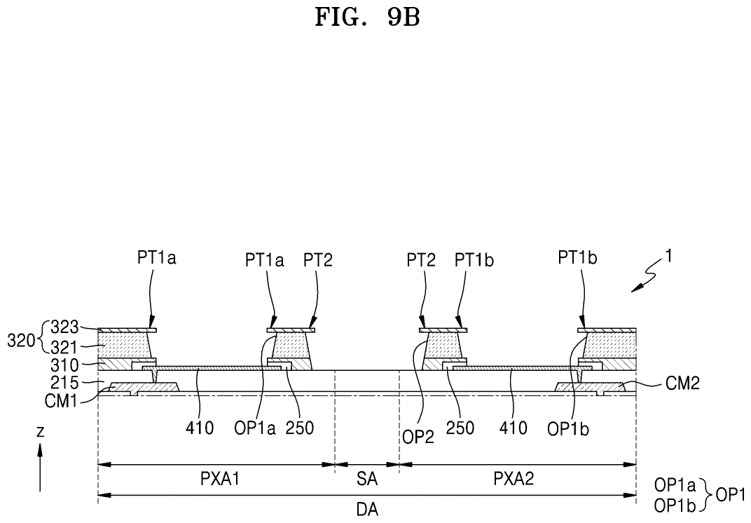

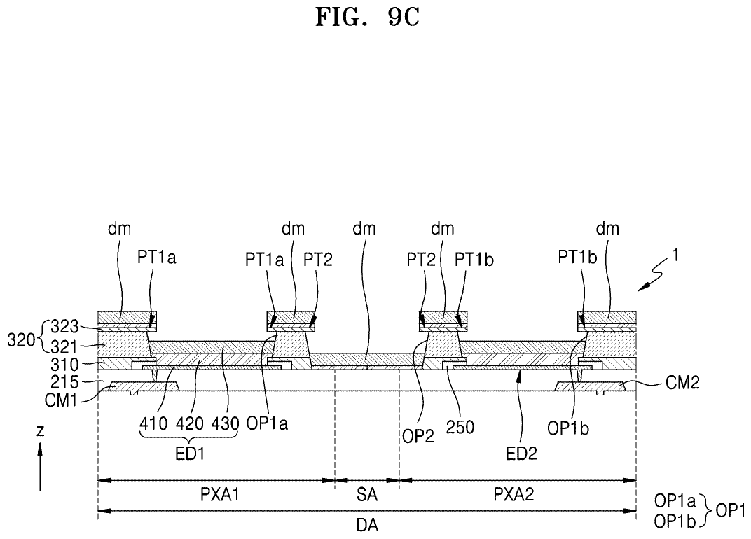

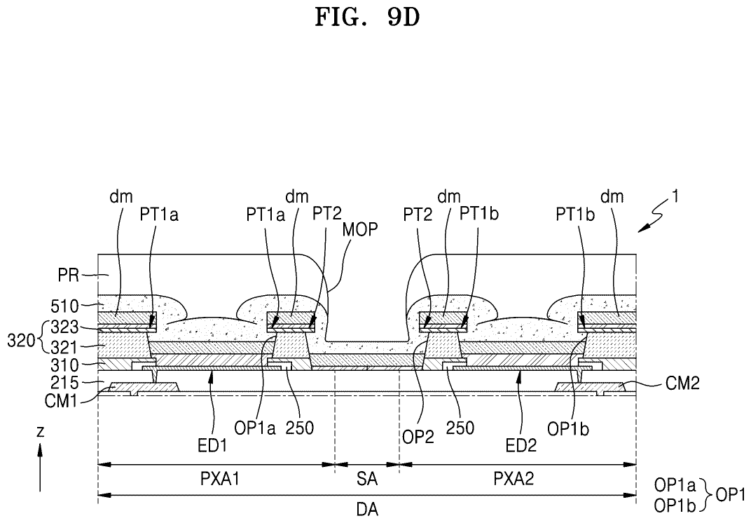

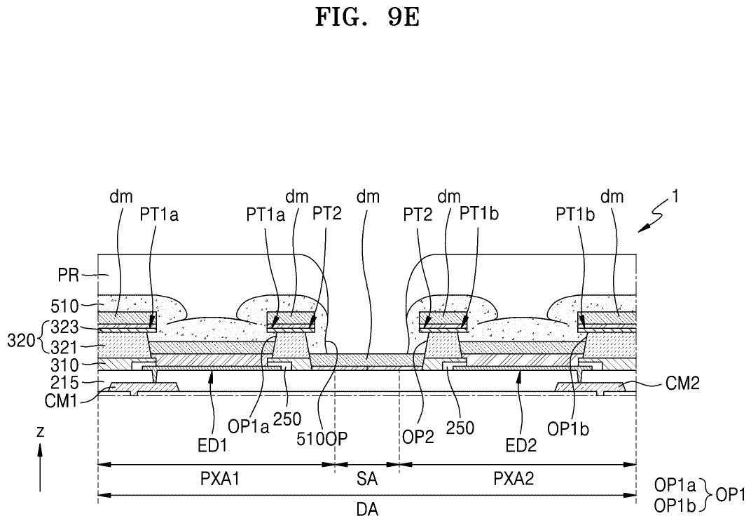

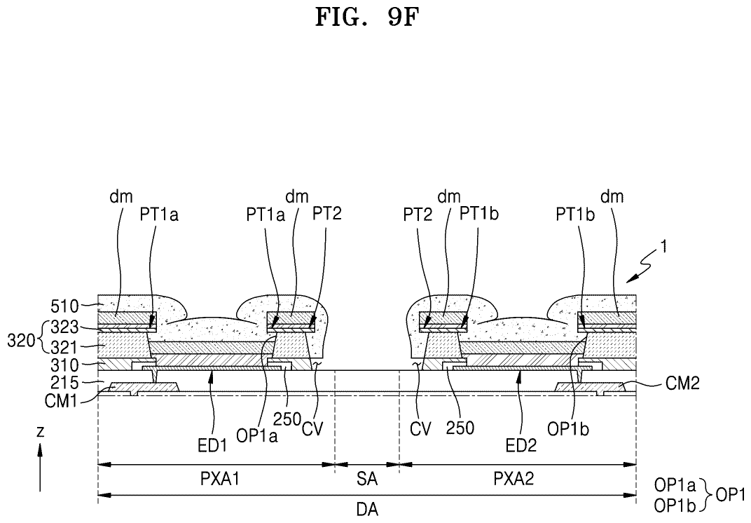

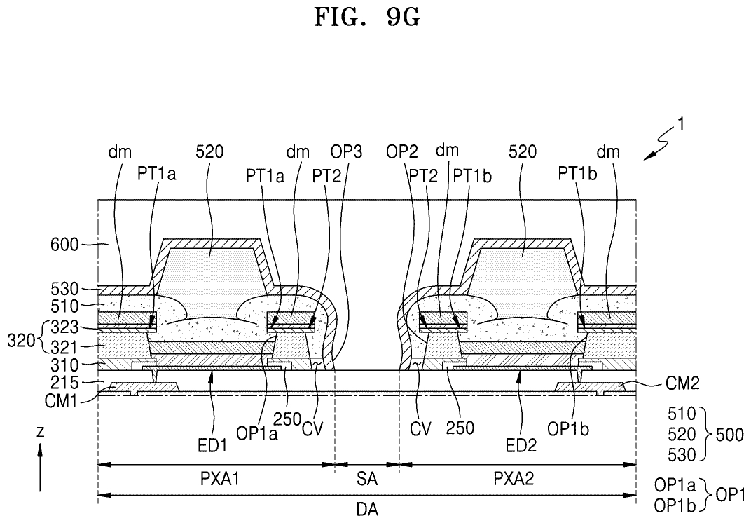

FIGS. 9A through 9G are cross-sectional views schematically illustrating an embodiment of a method of manufacturing a display device.

Referring to FIG. 9A, a display device 1 may include a first pixel area PXA1, a second pixel area PXA2, and a segmental area SA between the first pixel area PXA1 and the second pixel area PXA2.

First electrodes 410 may be disposed on the second planarization layer 215. Each of the first electrodes 410 may be electrically connected to a first connection electrode CM1 and a second connection electrode CM2 through a contact hole that penetrates the second planarization layer 215. The first electrode 410 disposed in the first pixel area PXA1 may be electrically connected to a first pixel driving circuit portion through the first connection electrode CM1, and the first electrode 410 disposed in the second pixel area PXA2 may be electrically connected to a second pixel driving circuit portion through the second connection electrode CM2.

Sacrificial layers 250 may be arranged to cover each of the first electrodes 410. The shape of the sacrificial layers 250 may correspond to the shape of the first electrode 410 disposed below the sacrificial layers 250. In an embodiment, the sacrificial layers 250 may include metal oxide such as IZO and/or indium gallium zinc oxide (“IGZO”).

A first bank layer 310 and a second bank layer 320 may be sequentially formed on the second planarization layer 215 to cover the sacrificial layers 250. The second bank layer 320 may include a first sub-bank layer 321 and a second sub-bank layer 323. In an embodiment, the first sub-bank layer 321 and the second sub-bank layer 323 may include conductive materials having different etch rates from each other. In another embodiment, the first sub-bank layer 321 and/or the second sub-bank layer 323 may include an inorganic insulating material.

Referring to FIG. 9B, a part of the first bank layer 310 and a part of the second bank layer 320 may be etched to define a first opening OP1 for exposing an upper surface of each of the first electrodes 410 and a second opening OP2 that overlaps the segmental area SA.

A central part of the first electrode 410 disposed in the first pixel area PXA1 may be exposed by the 1st-1 opening OP1a, and a central part of the first electrode 410 disposed in the second pixel area PXA2 may be exposed by the 1st-2 opening OP1b, and a part of an upper surface of the second planarization layer 215 may be exposed by the second opening OP2.

Through a wet etching process, a part of the first sub-bank layer 321 below the second sub-bank layer 323 may be additionally removed. Thus, the second sub-bank layer 323 may include a 1st-1 tip PT1a protruding toward the 1st-1 opening OP1a, and a 1st-2 tip PT1b protruding toward the 1st-2 opening OP1b, and a second tip PT2 protruding toward the second opening OP2. In other words, the second bank layer 320 may have an undercut structure.

The sacrificial layer 250 may protect an upper surface of the first electrode 410 while the first bank layer 310 and the second bank layer 320 are etched. Subsequently, the sacrificial layers 250 may be removed so that the upper surface of the first electrode 410 may be exposed. In this case, parts of the sacrificial layers 250 may remain between the first electrode 410 and the first bank layer 310.

Referring to FIG. 9C, a material for forming the intermediate layer 420 and a material for forming the second electrode 430 may be deposited on the structure as described above with reference to FIG. 9B.

The intermediate layer 420 may include a light-emitting layer. The light-emitting layer may be patterned by a fine metal mask, or the like, so as to correspond to each of the first electrodes 410. In an embodiment, a first light-emitting layer that emits a light of a first color may be patterned to correspond to the first electrode 410 of the first pixel area PXA1, and a second light-emitting layer that emits a light of a second color may be patterned to correspond to the first electrode 410 of the second pixel area PXA2, for example.

The intermediate layer 420 may include a first functional layer disposed between the first electrode 410 and the light-emitting layer and/or a second functional layer disposed between the light-emitting layer and the second electrode 430. The material for forming the first functional layer and the material for forming the second functional layer may be deposited on the entirety of the surface of the display area DA, and dummy stacks dm may be formed on the upper surface of the second sub-bank layer 323 and the upper surface of the second planarization layer 215 exposed by the second opening OP2.

The second electrode 430 may be disposed on the intermediate layer 420. The material for forming the second electrode 430 may be deposited on the entirety of the surface of the display area DA, and dummy stacks dm may be formed on the upper surface of the second sub-bank layer 323 and the upper surface of the second planarization layer 215 exposed by the second opening OP2.

The dummy stacks dm may be spaced apart from and separated from the intermediate layer 420 and the second electrode 430 of the first light-emitting diode ED1 by the 1st-1 tip PT1a and may be spaced apart from and separated from the intermediate layer 420 and the second electrode 430 of the second light-emitting diode ED2 by the 1st-2 tip PT1b. The dummy stacks dm disposed on the upper surface of the second sub-bank layer 323 may be spaced apart from and separated from the dummy stacks dm disposed inside the second opening OP2 by the second tip PT2.

The first electrode 410, the intermediate layer 420, and the second electrode 430, which are arranged in the first pixel area PXA1, may form the first light-emitting diode ED1, and the first electrode 410, the intermediate layer 420, and the second electrode 430, which are arranged in the second pixel area PXA2, may form the second light-emitting diode ED2.

Referring to FIG. 9D, a first inorganic encapsulation layer 510 may be formed to cover the first light-emitting diode ED1 and the second light-emitting diode ED2. The first inorganic encapsulation layer 510 may be formed by a CVD method or the like. The first inorganic encapsulation layer 510 may have a relatively excellent step coverage and may be in direct contact with a surface of the first sub-bank layer 321 and a surface of the second sub-bank layer 323 that are not covered by the intermediate layer 420 and the second electrode 430.

A photoresist PR may be formed on the first inorganic encapsulation layer 510. The photoresist PR may define a mask opening MOP that overlaps the second opening OP2.

Referring to FIG. 9E, a part of the first inorganic encapsulation layer 510 exposed through the mask opening MOP may be etched to define a first sub-opening 510OP in the first inorganic encapsulation layer 510. A part of the first inorganic encapsulation layer 510 disposed in the first pixel area PXA1 and a part of the first inorganic encapsulation layer 510 disposed in the second pixel area PXA2 may be separated from each other by the first sub-opening 510OP. The dummy stacks dm inside the second opening OP2 may be exposed by the first sub-opening 510OP.

Referring to FIG. 9F, the photoresist PR may be removed by a wet etching process. In a process of removing the photoresist PR, the dummy stacks dm inside the second opening OP2 may be removed, and cavities CV may be defined between a lower surface of the first inorganic encapsulation layer 510 and the second planarization layer 215. The dummy stacks dm on the upper surface of the second sub-bank layer 323 covered by the first inorganic encapsulation layer 510 may remain. The cavities CV may overlap the second opening OP2.

FIGS. 9D through 9F illustrate that the photoresist PR is used to pattern the first inorganic encapsulation layer 510 including photosensitive resin, but the disclosure is not limited thereto. In an embodiment, a metal oxide layer such as IZO and/or IGZO may be used as a mask so as to pattern the first inorganic encapsulation layer 510.

Referring to FIG. 9G, an organic encapsulation layer 520 may be formed on the first inorganic encapsulation layer 510, and a second inorganic encapsulation layer 530 may be formed to cover the organic encapsulation layer 520.

The organic encapsulation layer 520 may be disposed to correspond to each of the first light-emitting diodes ED1 and the second light-emitting diode ED2 through an inkjet process or a photo-patterning process. In an embodiment, the organic encapsulation layer 520 for burying the 1st-1 opening OP1a may be spaced apart from the organic encapsulation layer 520 for burying the 1st-2 opening OP1b, for example. In another embodiment, as described above with reference to FIG. 7C, the organic encapsulation layer 520 may be disposed to cover all of two or more light-emitting diodes disposed in the same pixel area.

The second inorganic encapsulation layer 530 may be formed on the entirety of the surface of the display area DA by CVD or the like. The second inorganic encapsulation layer 530 may extend to a bottom surface of the second opening OP2 from a side surface of the first inorganic encapsulation layer 510 to cover the cavities CV.

Subsequently, a part of the second inorganic encapsulation layer 530 that overlaps the segmental area SA may be removed by the patterning process or the like, thereby forming a third opening OP3. A part of the second inorganic encapsulation layer 530 disposed in the first pixel area PXA1 and a part of the second inorganic encapsulation layer 530 disposed in the second pixel area PXA2 may be separated from each other by the third opening OP3. The first inorganic encapsulation layer 510 and the second inorganic encapsulation layer 530 may be in direct contact with each other outside the organic encapsulation layer 520, thereby forming an inorganic contact region.

A third planarization layer 600 may be disposed on the encapsulation layer 500. The third planarization layer 600 may provide a flat base surface to components arranged above the third planarization layer 600. The third planarization layer 600 may include polymer resin having a relatively low modulus of about 3 MPa to about 20 MPa.

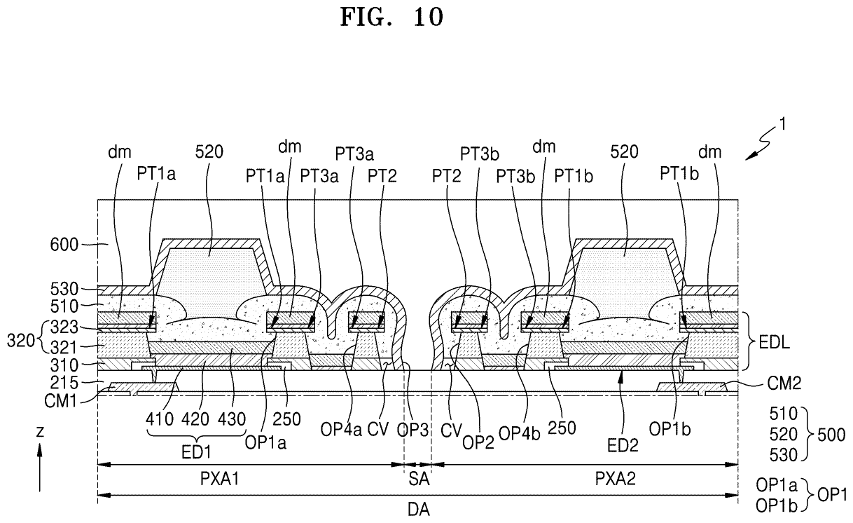

FIG. 10 is a cross-sectional view schematically illustrating an embodiment of a display device.

Referring to FIG. 10, a display device 1 may include a first pixel area PXA1, a second pixel area PXA2, and a segmental area SA between the first pixel area PXA1 and the second pixel area PXA2.

The first light-emitting diode ED1 may be disposed in the first pixel area PXA1, and the second light-emitting diode ED2 may be disposed in the second pixel area PXA2. Each of the first light-emitting diode ED1 and the second light-emitting diode ED2 may include a first electrode 410, a second electrode 430 on the first electrode 410, and an intermediate layer 420 between the first electrode 410 and the second electrode 430.

A first electrode 410 of the first light-emitting diode ED1 and a first electrode 410 of the second light-emitting diode ED2 may be spaced apart from each other and disposed on the second planarization layer 215. The first electrode 410 of the first light-emitting diode ED1 may be electrically connected to a first pixel driving circuit portion through the first connection electrode CM1. The first electrode 410 of the second light-emitting diode ED2 may be electrically connected to a second pixel driving circuit portion through the second connection electrode CM2.

The first bank layer 310 may be disposed on the second planarization layer 215 to cover an edge of each of the first electrodes 410. The second bank layer 320 may be disposed on the first bank layer 310. The second bank layer 320 may include a first sub-bank layer 321 and a second sub-bank layer 323 disposed on the first sub-bank layer 321.

The first bank layer 310 and the second bank layer 320 may define the first opening OP1 that overlaps the first electrode 410, a second opening OP2 that overlaps the segmental area SA, and fourth openings OP4a and OP4b between the first opening OP1 and the second opening OP2. The first opening OP1 may include a 1st-1 opening OP1a that overlaps the first electrode 410 of the first light-emitting diode ED1, and a 1st-2 opening OP1b that overlaps the first electrode 410 of the second light-emitting diode ED2. A 4th-1 opening OP4a may be disposed between the 1st-1 opening OP1a and the second opening OP2, and a 4th-2 opening OP4b may be disposed between the 1st-2 opening OP1b and the second opening OP2.

A part of the first bank layer 310 and a part of the second bank layer 320 disposed in the first pixel area PXA1 may be separated from a part of the first bank layer 310 and a part of the second bank layer 320 disposed in the second pixel area PXA2 by the second opening OP2. A part of the first bank layer 310 and a part of the second bank layer 320 disposed in the first pixel area PXA1 may be divided into an inside portion and an outside portion by the 4th-1 opening OP4a. Similarly, a part of the first bank layer 310 and a part of the second bank layer 320 disposed in the second pixel area PXA2 may be divided into an inside portion and an outside portion by the 4th-2 opening OP4b.

The second bank layer 320 may have an undercut structure in which a part of the first sub-bank layer 321 disposed under the second sub-bank layer 323 is removed. In an embodiment, the second sub-bank layer 323 may include a 1st-1 tip PT1a extending toward the 1st-1 opening OP1a, a 1st-2 tip PT1b extending toward the 1st-2 opening OP1b, a second tip PT2 extending toward the second opening OP2, a 3rd-1 tip PT3a extending toward the 4rd-1 opening OP4a, and a 3rd-2 tip PT3b extending toward the 4th-2 opening OP4b, for example.

The dummy stacks dm may be disposed on the upper surface of the second sub-bank layer 323, a bottom surface of the 4th-1 opening OP4a, and a bottom surface of the 4th-2 opening OP4b. The dummy stacks dm on the upper surface of the second sub-bank layer 323 and the dummy stacks dm disposed on the bottom surface of the 4th-1 opening OP4a may be spaced apart from and separated from each other by the 3rd-1 tip PT3a. The dummy stacks dm on the upper surface of the second sub-bank layer 323 and the dummy stacks dm disposed on the bottom surface of the 4th-2 opening OP4b may be spaced apart from and separated from each other by the 3rd-2 tip PT3b.

An encapsulation layer 500 may be disposed on the light-emitting diode layer EDL to cover the first light-emitting diode ED1 and the second light-emitting diode ED2. The encapsulation layer 500 may include a first inorganic encapsulation layer 510 and a second inorganic encapsulation layer 530. The first inorganic encapsulation layer 510 may be in direct contact with the surface of the first sub-bank layer 321 and the surface of the second sub-bank layer 323 that are not covered by the intermediate layer 420 and the second electrode 430, thereby forming an inorganic contact region. In an embodiment, the first inorganic encapsulation layer 510 may form an inorganic contact region in a lower part of the 1st-1 tip PT1a, a lower part of the 1st-2 tip PT1b, a lower part of the second tip PT2, a lower part of the 3rd-1 tip PT3a, and a lower part of the 3rd-2 tip PT3b, for example.

The first inorganic encapsulation layer 510 may define cavities CV that overlap the second opening OP2. The first inorganic encapsulation layer 510 may extend along the side of the first sub-bank layer 321 toward the second opening OP2 and may be spaced apart from the bottom surface of the second opening OP2 by the cavities CV. Four tips may be arranged between the cavities CV and the first light-emitting diode ED1, and four tips may be arranged between the cavities CV and the second light-emitting diode ED2.

The first inorganic encapsulation layer 510 and the second inorganic encapsulation layer 530 may define a third opening OP3 that overlaps the segmental area SA. A part of the first inorganic encapsulation layer 510 and a part of the second inorganic encapsulation layer 530 disposed in the first pixel area PXA1, and a part of the first inorganic encapsulation layer 510 and a part of the second inorganic encapsulation layer 530 disposed in the second pixel area PXA2 may be separated from each other by the third opening OP3.

An organic encapsulation layer 520 may be disposed between the first inorganic encapsulation layer 510 and the second inorganic encapsulation layer 530. The organic encapsulation layer 520 may bury the 1st-1 opening OP1a, the 1st-2 opening OP1b, the 4th-1 opening OP4a, and the 4th-2 opening OP4b, thereby providing a flatter base surface to components arranged above the organic encapsulation layer 520.

A third planarization layer 600 may be disposed on the encapsulation layer 500. The third planarization layer 600 may provide a flat base surface to components arranged above the third planarization layer 600, e.g., a touch input layer or the like.

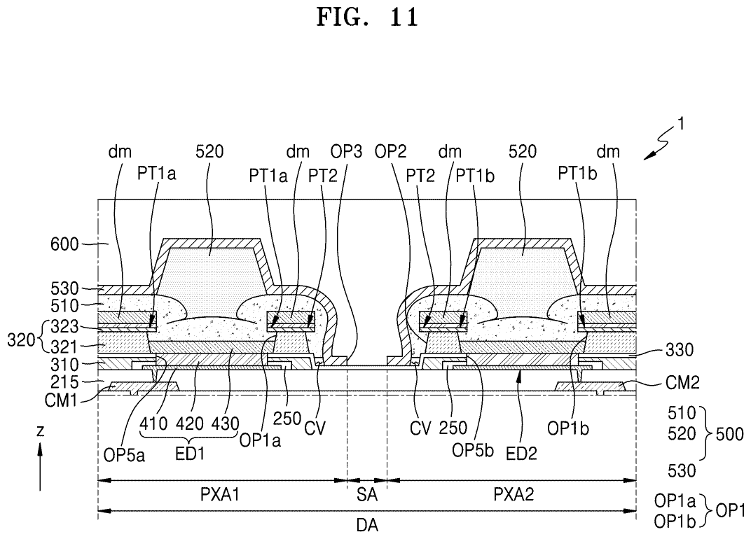

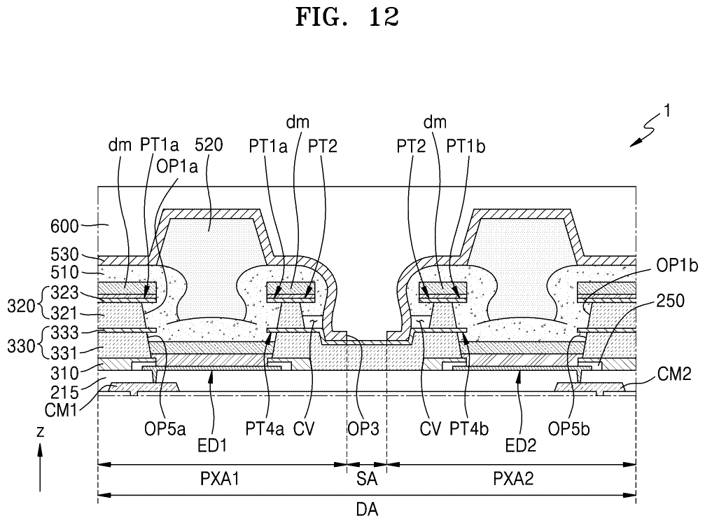

FIGS. 11 and 12 are cross-sectional views schematically illustrating an embodiment of a display device. A display device 1 shown in each of FIGS. 11 and 12 may be similar to the display device 1 shown in FIG. 5 but is different from the display device 1 of FIG. 5 by further including a conductive layer 330 between the first bank layer 310 and the second bank layer 320. Hereinafter, the same or similar explanation will be omitted and explained based on the difference.

Referring to FIGS. 11 and 12, a first bank layer 310 may be disposed on the second planarization layer 215 to cover an edge of each of the first electrodes 410. The first bank layer 310 may include an inorganic material such as silicon oxide, silicon nitride and/or silicon oxynitride, and may have a single layer or multi-layered structure. In an embodiment, a sacrificial layer 250 may be disposed between the first bank layer 310 and the first electrodes 410.

The conductive layer 330 may be disposed on the first bank layer 310, and the second bank layer 320 may be disposed on the conductive layer 330. The conductive layer 330 may extend to the second pixel area PXA2 from the first pixel area PXA1 through the segmental area SA. The conductive layer 330 may define a 5th-1 opening OP5a that overlaps the 1st-1 opening OP1a and a 5th-2 opening OP5b that overlaps the 1st-2 opening OP1b. The conductive layer 330 may be unitary as a single body on the entirety of the surface of the display area DA. Thus, the conductive layer 330 may extend along the side surface of the first bank layer 310 toward the second opening OP2 and may form a bottom surface of the third opening OP3.

The conductive layer 330 may include a conductive material, e.g., Mo, Al, Cu, Ti, or the like, and may have a single layer or multi-layered structure. In an embodiment, as shown in FIG. 11, the conductive layer 330 may be formed in a single layer structure.

In another embodiment, as shown in FIG. 12, the conductive layer 330 may have a multi-layered structure. In an embodiment, the conductive layer 330 may include a first sub-conductive layer 331, and a second sub-conductive layer 333 on the first sub-conductive layer 331, for example. In an embodiment, the first sub-conductive layer 331 and the second sub-conductive layer 333 may include conductive materials having different etch rates from each other. In this case, the conductive layer 330 may have an undercut structure in which a part of the first sub-conductive layer 331 disposed under the second sub-conductive layer 333 is removed. In an embodiment, the second sub-conductive layer 333 may include a 4th-1 tip PT4a protruding from the side surface of the first sub-conductive layer 331 toward the 1st-1 opening OP1a (or a 5th-1 opening OP5a), and a 4th-2 tip PT4b protruding from the side surface of the first sub-conductive layer 331 toward the 1st-2 opening OP1b (or a 5th-2 opening OP5b), for example. The first inorganic encapsulation layer 510 may be in direct contact with the surface of the first sub-bank layer 321 and the surface of the second sub-bank layer 323 below the 4th-1 tip PT4a and the 4th-2 tip PT4b, thereby forming an inorganic contact region. In an embodiment, the 4th-1 tip PT4a may extend toward the 1st-1 opening OP1a (or a 5th-1 opening OP5a), and the 4th-2 tip PT4b may extend toward the 1st-2 opening OP1b (or a 5th-2 opening OP5b).

The second electrode 430 of the first light-emitting diode ED1 may be in direct contact with the conductive layer 330 inside the 1st-1 opening OP1a, and the second electrode 430 of the second light-emitting diode ED2 may be in direct contact with the conductive layer 330 inside the 1st-2 opening OP1b. The conductive layer 330 may contact a second power supply voltage line, etc., in the non-display area (refer to NDA of FIG. 1) and may transmit the second power supply voltage to the second electrodes 430. When the display device 1 further includes the conductive layer 330, a contact hole for electrically connecting the first sub-bank layer 321 to the power supply voltage line (refer to VL of FIG. 7B) may be omitted. Thus, pixels may be more densely disposed, thereby providing the display device 1 having relatively high resolution.

An encapsulation layer 500 may be disposed to cover the first light-emitting diode ED1 and the second light-emitting diode ED2. The encapsulation layer 500 may include a first inorganic encapsulation layer 510, a second inorganic encapsulation layer 530, and an organic encapsulation layer 520 disposed between the first inorganic encapsulation layer 510 and the second inorganic encapsulation layer 530.

The first inorganic encapsulation layer 510 may define cavities CV that overlap the second opening OP2. The second inorganic encapsulation layer 530 may cover each of the first pixel area PXA1 and the second pixel area PXA2. The first inorganic encapsulation layer 510 and the second inorganic encapsulation layer 530 may define a third opening OP3 that overlaps the segmental area SA. An organic encapsulation layer 520 may be disposed between the first inorganic encapsulation layer 510 and the second inorganic encapsulation layer 530. A third planarization layer 600 may be disposed on the encapsulation layer 500.

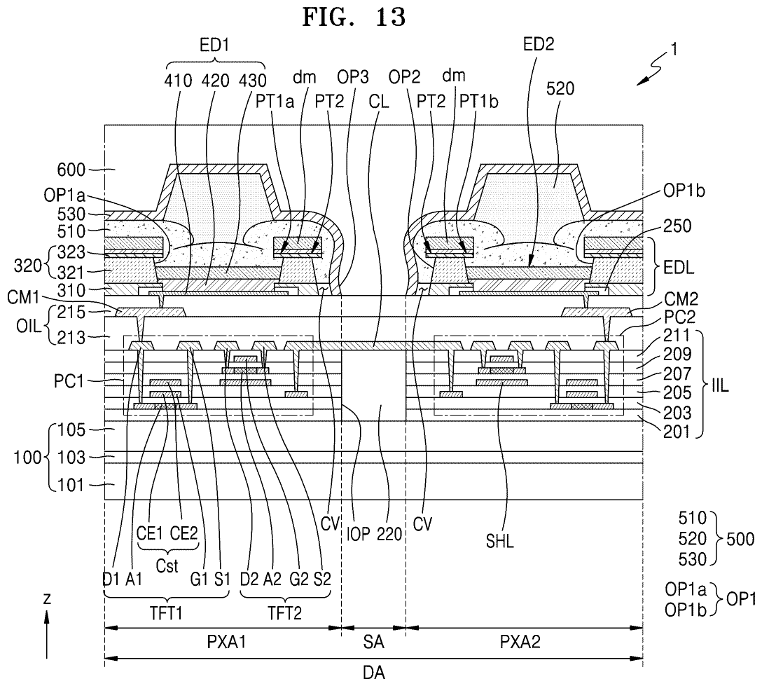

FIG. 13 is a cross-sectional view schematically illustrating an embodiment of a display device 1. The display device 1 shown in FIG. 13 is similar to the display device 1 shown in FIG. 5 but is different from the display device 1 of FIG. 5 in that an inorganic insulating layer IIL further defines an inorganic opening IOP that overlaps the segmental area SA.

Referring to FIG. 13, the display device 1 may include a first pixel area PXA1, a second pixel area PXA2, and a segmental area SA between the first pixel area PXA1 and the second pixel area PXA2.

A first pixel driving circuit portion PC1, a second pixel driving circuit portion PC2, and an inorganic insulating layer IIL may be arranged on a substrate 100. The inorganic insulating layer IIL may include inorganic material layers arranged between the substrate 100 and a light-emitting diode layer EDL. In an embodiment, the inorganic insulating layer IIL may include a buffer layer 201, a first gate insulating layer 203, a second gate insulating layer 205, a first inter-insulating layer 207, a third gate insulating layer 209 and a second inter-insulating layer 211, for example.

The inorganic insulating layer IIL may overlap the segmental area SA and may define the inorganic opening IOP for exposing an upper surface of a second base layer 105. The inorganic opening IOP may also be defined by overlapping an opening of a buffer layer 201, an opening of a first gate insulating layer 203, an opening of a second gate insulating layer 205, an opening of a first inter-insulating layer 207, an opening of a third gate insulating layer 209, and an opening of a second inter-insulating layer 211. A part of the inorganic insulating layer IIL disposed in the first pixel area PXA1 may be separated from a part of the inorganic insulating layer IIL disposed in the second pixel area PXA2 may be separated from each other by the inorganic opening IOP. On a plane, the inorganic opening IOP may surround each of the first pixel driving circuit portion PC1 and the second pixel driving circuit portion PC2.

The inorganic opening IOP may be filled by a filling layer 220. In an embodiment, an upper surface of the filling layer (or filling material) 220 may be disposed at a level that is the same as or similar to a level of an upper surface of the second inter-insulating layer 211, i.e., an uppermost surface of the inorganic insulating layer IIL. In another embodiment, the upper surface of the filling layer 220 may have a convex shape higher than the uppermost surface of the inorganic insulating layer IIL also may have a concave shape lower than the uppermost surface of the inorganic insulating layer IIL, or may have a shape with unevenness in which protrusions and recesses are alternately formed. The filling layer 220 may include a polymer resin. The polymer resin may include an acryl-based resin, an epoxy-based resin, polyimide, polyethylene, or the like.

A connection line CL for connecting components of the first pixel driving circuit portion PC1 and components of the second pixel driving circuit portion PC2 to each other may be disposed on the filling layer 220. The connection line CL may be disposed between the filling layer 220 and the first planarization layer 213. The connection line CL may include a conductive material, e.g., Mo, Al, Cu, Ti, or the like, and may have a single layer or multi-layered structure.

FIG. 13 illustrates that a width of the segmental area SA and a width of the inorganic opening IOP are the same, but the disclosure is not limited thereto. In an embodiment, the width of the segmental area SA may be different from the width of the inorganic opening IOP. Also, the segmental area SA and the inorganic opening IOP may overlap partially or may be offset.

When the display device 1 is elongated or is bent, the inorganic opening IOP may disperse stress concentrated on a part of the inorganic insulating layer IIL. Thus, defects such as cracks of the inorganic insulating layer IIL may be reduced or prevented, and the elongation rate of the display device 1 may be enhanced.

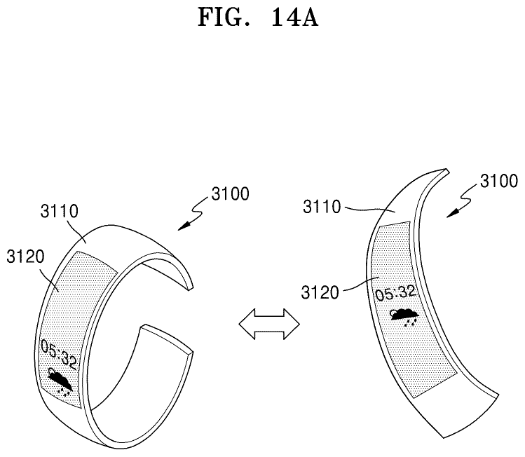

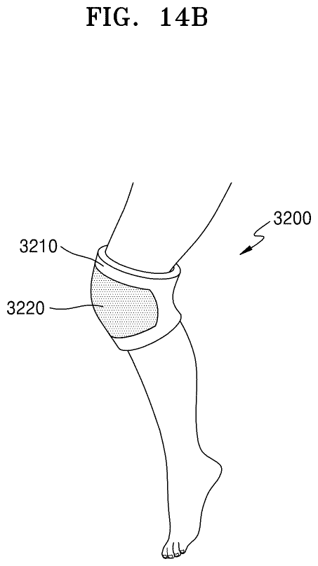

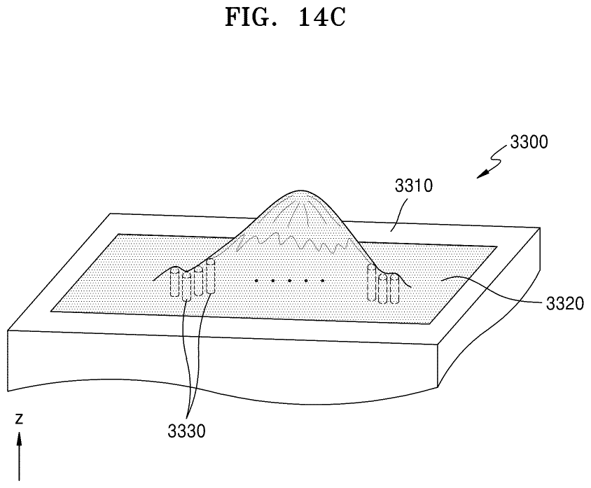

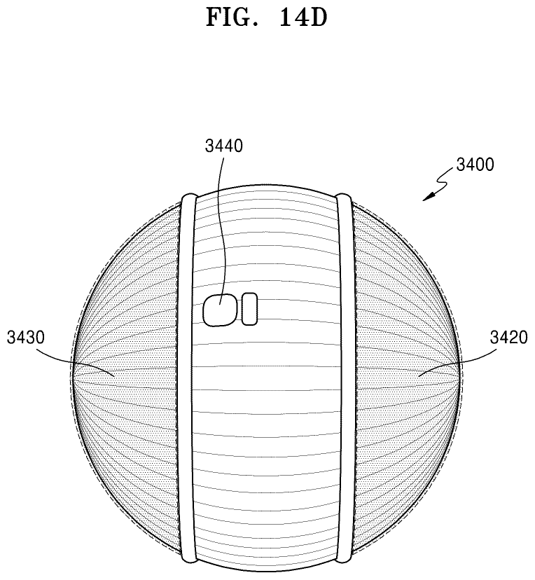

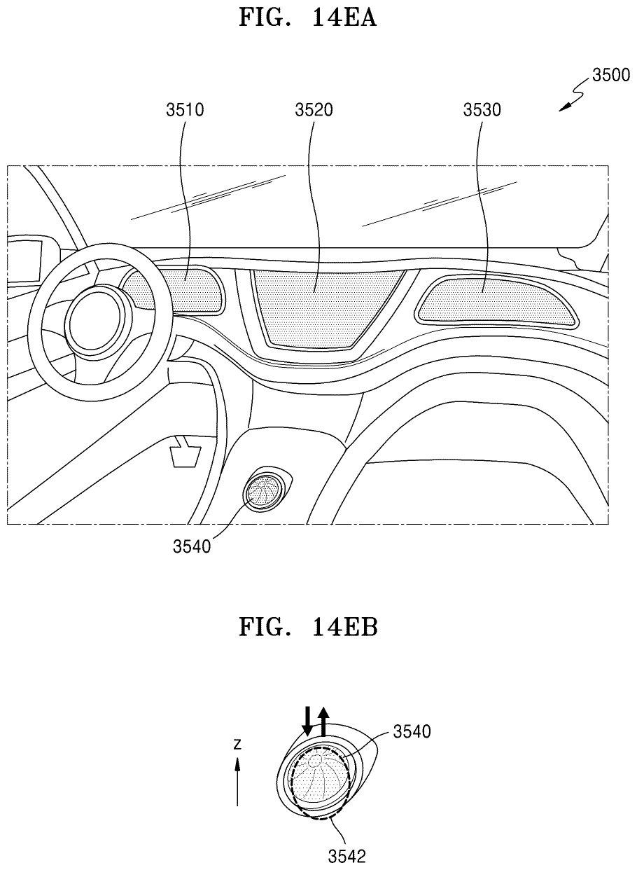

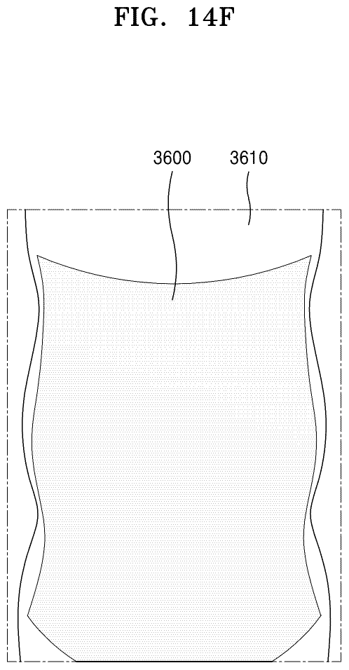

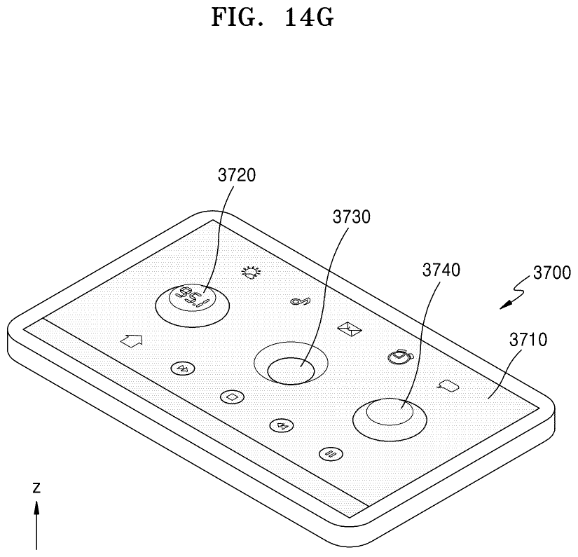

FIGS. 14A through 14G are perspective views schematically illustrating an embodiment of electronic apparatuses including a display device.

Referring to FIG. 14A, the display device in an embodiment may be used in a wearable electronic apparatus 3100 that is wearable on a part of the user's body. The wearable electronic apparatus 3100 may include a body unit 3110, and a display unit 3120 provided in the body unit 3110. The display device in embodiments may be used as the display unit 3120 of the wearable electronic apparatus 3100. As shown in FIG. 14A, the wearable electronic apparatus 3100 may be deformable. In an embodiment, the wearable electronic apparatus 3100 may be used as a smart watch or smartphone according to the user's selection.

FIG. 14B illustrates a medical electronic apparatus 3200. In an embodiment, the medical electronic apparatus 3200 may include a body unit 3210 and a light-emitting unit 3220. The display device in embodiments may be used as the light-emitting unit 3220 of the medical electronic apparatus 3200. The light-emitting unit 3220 may emit light having a predetermined wavelength band (e.g., infrared rays, visible rays, etc.) onto a patient's body. In an embodiment, the body unit 3210 may have a stretchable fiber material and may have a structure that is wearable onto the body of the light-emitting unit's user.

FIG. 14C illustrates an educational electronic apparatus 3300. In an embodiment, the educational electronic apparatus 3300 may include a display unit 3320 provided in a frame 3310. The display unit 3320 may use embodiments of a display device. The display unit 3320 may provide an image such as the sea striking the waves, the mountain covered with snow, or the volcano with the lava, and at this time, the display unit 3320 may reflect the height of the waves, mountains or volcanoes and may be elongated in a height direction (e.g., a z direction). In some embodiments, a part of the display unit 3320 may show the movement of lava in three dimensions when the height of the display unit 3320 varies sequentially in the direction of the lava flow. The educational electronic apparatus 3300 may include a plurality of pins (or strokes) 3330 disposed on a rear surface of the display unit 3320 so that the display unit 3320 may be elongated in the height direction. As the plurality of pins 3330 move in a third direction (e.g., a z direction or a −z direction), images expressed on the display unit 3320 may have a height in three dimensions. FIG. 14C illustrates the educational electronic apparatus 3300, but, in the case of an electronic apparatus capable of providing predetermined image information, the use of the electronic apparatus is not limited.

The electronic apparatuses shown in FIGS. 14A through 14C has variable shapes, but the disclosure is not limited thereto. As in embodiments described later, a display device in embodiments may be used for an electronic apparatus with a unit (e.g., a screen) on which a unit capable of expressing images is fixed.

FIG. 14D illustrates a robot 3400 as another electronic apparatus. The robot 3400 may recognize movement or an object by a camera unit 3440 and may display a predetermined image to the user through a display unit 3420 or 3430. In some embodiments, display devices in an embodiment may be elongated in various directions, as described above, and may be assembled on a body frame having a semi-spherical shape. Thus, the robot 3400 may include spherical display units 3420 and 3430.

FIG. 14EA illustrates an embodiment of a vehicle display apparatus 3500 as an electronic apparatus. The vehicle display apparatus 3500 may include a cluster 3510, a center information display (“CID”) 3520 and/or a passenger display 3530. The display device in an embodiment may be elongated in various directions and thus, may be used as the cluster 3510, the CID 3520 and/or the passenger display (or a co-driver display) 3530 while the display device is not limited by the shape of an inner frame of a vehicle.

FIG. 14EA illustrates that the cluster 3510, the CID 3520 and/or the co-driver display 3530 are separated from each other, but the disclosure is not limited thereto. In another embodiment, two or more selected from the cluster 3510, the CID 3520 and/or the co-driver display 3530 may be unitary with each other as a single body.

In some embodiments, the vehicle display apparatus 3500 may include a button 3540 that may express a predetermined image. Referring to FIG. 14EB which is the enlarged view of a portion of FIG. 14EA, a semi-spherical button 3540 may include an object 3542 that provides a button use feeling while moving in the z direction or −z direction, and a display device disposed on the object 3542. In some embodiments, when the object 3542 includes a three-dimensionally rounded surface, the display device may include a three-dimensionally rounded surface.

FIG. 14F illustrates that an electronic apparatus in an embodiment is an advertising or exhibition electronic apparatus 3600. In some embodiments, the advertising or exhibition electronic apparatus 3600 may be installed on a fixed structure 3610, like a wall or pillar. When the structure 3610 includes uneven surfaces, as shown in FIG. 14F, the advertising or exhibition electronic apparatus 3600 may be disposed along the uneven surfaces of the structure 3610. In some embodiments, the advertising or exhibition electronic apparatus 3600 may be installed on the structure 3610 by a thermal contraction film or the like.

FIG. 14G illustrates an embodiment of a controller 3700 as an electronic apparatus. The controller 3700 may include an image type button. In an embodiment, the controller 3700 may include first through third button areas 3720, 3730, and 3740 in which partial regions of the display unit 3710 protrude in the z direction or protrude −z direction (or are recessed in the z direction), for example. In some embodiments, the first button area 3720 and third button area 3740 may protrude in the z direction, and the second button area 3730 may protrude in the −z direction (or may be recessed in the z direction).

According to embodiments described above, a display device having an enhanced elongation rate may be implemented. Of course, the scope of the disclosure is not limited by these effects.

It should be understood that embodiments described herein should be considered in a descriptive sense only and not for purposes of limitation. Descriptions of features or advantages within each embodiment should typically be considered as available for other similar features or advantages in other embodiments. While embodiments have been described with reference to the drawing figures, it will be understood by those of ordinary skill in the art that various changes in form and details may be made therein without departing from the spirit and scope as defined by the following claims.

What is claimed is:

1. A display device comprising:
a substrate including a first area and a second area surrounding the first area;
a first electrode disposed in the first area;
a first bank layer disposed on the first electrode and defining a first opening that overlaps the first electrode and a second opening that overlaps the second area, the first bank layer comprising:
a first sub-bank layer; and
a second sub-bank layer disposed on the first sub-bank layer and including:
a first tip extending toward the first opening; and
a second tip extending toward the second opening;
an intermediate layer disposed on the first electrode;
a second electrode disposed on the intermediate layer; and
an encapsulation layer disposed on the second electrode and defining a third opening that overlaps the second area.

2. The display device of claim 1, wherein the encapsulation layer comprises:
a first encapsulation layer disposed on the second electrode and being in contact with the first sub-bank layer below the first tip and below the second tip; and
a second encapsulation layer disposed on the first encapsulation layer.

3. The display device of claim 2, wherein the first encapsulation layer defines cavities that overlap the second opening, and the second encapsulation layer extends to cover the cavities.

4. The display device of claim 2, wherein the encapsulation layer further comprises a third encapsulation layer between the first encapsulation layer and the second encapsulation layer, the third encapsulation layer overlaps the first opening, and the second encapsulation layer contacts the first encapsulation layer outside the third encapsulation layer.

5. The display device of claim 1, further comprising:
an inorganic insulating layer between the substrate and the first electrode and defining an opening that overlaps the second area; and
a filling material filling in the opening of the inorganic insulating layer.

6. The display device of claim 1, wherein each of the first sub-bank layer and the second sub-bank layer comprise conductive materials.

7. The display device of claim 1, wherein the first sub-bank layer comprises a conductive material or an inorganic insulating material, and the second sub-bank layer comprises an inorganic insulating material.

8. The display device of claim 1, further comprising:
a second bank layer between the first electrode and the first bank layer; and
a conductive layer between the second bank layer and the first bank layer and extending into the second area.

9. The display device of claim 8, wherein the first area is provided in plural, and the conductive layer connects adjacent first areas across the second area.

10. The display device of claim 8, wherein the conductive layer comprises a first sub-conductive layer and a second sub-conductive layer, the second sub-conductive layer being disposed on the first sub-conductive layer and including a third tip extending toward the first opening.

11. The display device of claim 1, further comprising dummy stacks disposed on the second sub-bank layer, wherein the intermediate layer and the second electrode are separated from and spaced apart from the dummy stacks by the first tip.

12. A display device comprising:
a substrate including a first area and a second area surrounding the first area;
a first electrode disposed in the first area;
a first bank layer disposed on the first electrode and defining a first opening that overlaps the first electrode, a second opening that overlaps the second area, and a third opening between the first opening and the second opening, the first bank layer comprising:
a first sub-bank layer; and
a second sub-bank layer disposed on the first sub-bank layer and including:
a first tip extending toward the first opening;
a second tip extending toward the second opening; and
a third tip extending toward the third opening;
an intermediate layer disposed on the first electrode;
a second electrode disposed on the intermediate layer; and
an encapsulation layer disposed on the second electrode and defining a fourth opening that overlaps the second area.

13. The display device of claim 12, wherein the encapsulation layer comprises:
a first encapsulation layer disposed on the second electrode and being in contact with the first sub-bank layer below the first tip, below the second tip, and below the third tip; and
a second encapsulation layer disposed on the first encapsulation layer.

14. The display device of claim 13, wherein the first encapsulation layer defines cavities that overlap the second opening, and the second encapsulation layer covers the cavities.

15. The display device of claim 13, wherein the encapsulation layer further comprises a third encapsulation layer between the first encapsulation layer and the second encapsulation layer, the third encapsulation layer overlaps the first opening, and the second encapsulation layer contacts the first encapsulation layer outside the third encapsulation layer.

16. The display device of claim 12, further comprising:
an inorganic insulating layer between the substrate and the first electrode and defining an opening that overlaps the second area; and
a filling material filling in the opening of the inorganic insulating layer.

17. The display device of claim 12, wherein each of the first sub-bank layer and the second sub-bank layer comprise conductive materials.

18. The display device of claim 12, wherein the first sub-bank layer comprises a conductive material or an inorganic insulating material, and the second sub-bank layer comprises an inorganic insulating material.

19. The display device of claim 12, further comprising:
a second bank layer between the first electrode and the first bank layer; and
a conductive layer between the second bank layer and the first bank layer and extending into the second area.

20. The display device of claim 19, wherein the first area is provided in plural, and the conductive layer connects adjacent first areas across the second area.
